(19) United States
(12) Patent Application Publication
(10) Pub. No.: US 2008/0157081 A1
(43) Pub. Date: Jul. 3, 2008

(54) ORGANIC LIGHT EMITTING DEVICE AND METHOD FOR MANUFACTURING THE SAME

(75) Inventor: Jong-Moo HUH, Hwaseong-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/845,202

(22) Filed: Aug. 27, 2007

(30) Foreign Application Priority Data
Dec. 28, 2006 (KR) 10-2006-0136160
Mar. 23, 2007 (KR) 10-2007-0028460

(51) Int. Cl. G09G 3/10; H01L 21/84; H01L 29/04

(52) U.S. Cl. 257/59; 315/169.3; 438/164; 257/E21.7; 257/E29.003

(57) ABSTRACT

An organic light emitting device includes a substrate, first and second signal lines formed on the substrate, a switching thin film transistor (“TFT”) connected to the first and second signal lines and including a first semiconductor, a driving TFT including a second semiconductor, an etch stopper formed on the second semiconductor, driving input and driving output electrodes overlapping the etch stopper and the second semiconductor and opposite to each other with respect to the etch stopper, and a driving control electrode connected to the switching TFT and overlapping the second semiconductor, a first electrode connected to the driving output electrode, a second electrode opposite to the first electrode, and an organic light emitting member, wherein at least one of the etch stopper, the driving input electrode, and the driving output electrode is symmetrical with respect to one straight line.

This application claims priority to Korean Patent Applications Nos. 10-2006-0136160 filed on Dec. 28, 2006, and 10-2007-0028460 filed on Mar. 23, 2007, and all the benefits accruing therefrom under 35 U.S.C. §119, and the contents of which in their entireties are herein incorporated by reference.

### BACKGROUND OF THE INVENTION

(a) Field of the Invention

The present invention relates to an organic light emitting device and a method for manufacturing the same. More particularly, the present invention relates to an organic light emitting device improving electrical characteristics thereof, and a method for manufacturing the organic light emitting device.

(b) Description of the Related Art

Recent trends toward lightweight and thin personal computers and televisions sets also require lightweight and thin display devices, and flat panel displays such as a liquid crystal display (“LCD”) satisfying such a requirement are being substituted for conventional cathode ray tubes (“CRTs”).

However, because the LCD is a passive display device, an additional backlight as a light source is needed, and the LCD has various problems such as a slow response time and a narrow viewing angle.

Among the flat panel displays, an organic light emitting device has recently been the most promising as a display device for solving these problems.

The organic light emitting device is a self emissive display device, which includes two electrodes and an organic light emitting layer interposed between the two electrodes. One of the two electrodes injects holes and the other injects electrons into the light emitting layer. The injected electrons and holes are combined to form excitons and the excitons emit light as discharge energy.

Among the flat panel displays, the organic light emitting device is the most promising because of its low power consumption, fast response time, wide viewing angle, and high contrast ratio.

Organic light emitting devices are divided into a passive matrix organic light emitting device and an active matrix organic light emitting device according to driving type.

The active matrix organic light emitting device display includes a plurality of switching thin film transistors (“TFTs”) connected to signal lines that cross each other, a plurality of driving TFTs connected to switching TFTs and driving voltage lines, and a plurality of emitting portions connected to driving TFTs.

### BRIEF SUMMARY OF THE INVENTION

For the optimized characteristics of the OLED, characteristics of the switching thin film transistor (“TFT”) and those of the driving TFT may be different from each other. In particular, the switching TFT may have a good on/off characteristic, and the driving TFT may have high mobility and stability for supplying sufficient current for driving the OLED.

If the off current of the switching TFT is increased, then the data voltage transported to the driving TFT may be reduced to generate cross-talk. If the driving TFT has low mobility and stability, display characteristic deterioration such as a reduction in current transmitted to the light-emitting device, an image sticking phenomenon, a life-time reduction, etc., may occur.

The present invention improves the electrical characteristics of an organic light emitting device by simultaneously satisfying the characteristics of a driving TFT and a switching TFT.

In exemplary embodiments of the present invention, an organic light emitting device includes a substrate, first and second signal lines formed on the substrate, a switching TFT connected to the first and second signal lines and including a first semiconductor, a driving TFT including a second semiconductor, an etch stopper formed on the second semiconductor, driving input and driving output electrodes overlapping the etch stopper and the second semiconductor and being opposite to each other with respect to the etch stopper, and a driving control electrode connected to the switching TFT and overlapping the second semiconductor, a first electrode connected to the driving output electrode, a second electrode opposite to the first electrode, and an organic light emitting member, wherein at least one of the etch stopper, the driving input electrode, and the driving output electrode is symmetrical with respect to one straight line.

The second semiconductor may have a first portion and a second portion separated from the first portion. The etch stopper may be track-shaped, such as including a running oval shape, and the driving input electrode may overlap an inner portion of the etch stopper, and the driving output electrode overlap an outer portion of the etch stopper. The driving output electrode may include first and second portions disposed on opposing sides of the etch stopper, and a third portion connecting the first and second portions of the etch stopper to each other.

The organic light emitting device may further include a third signal line connected to the driving input electrode of the driving TFT. The etch stopper, the driving input electrode, and the driving output electrode may be symmetrical with respect to the third signal line. The driving output electrode and the second semiconductor may each respectively have two portions and the two portions of each of the driving output electrode and the second semiconductor are separated from each other at opposite sides with respect to the third signal line.

The driving input electrode may include a first portion and a second portion separated from the first portion of the driving input electrode, and the organic light emitting device may further include a first driving voltage line connected to the first portion of the driving input electrode and a second driving voltage line connected to the second portion of the driving input electrode. The etch stopper and the driving output electrode may each include first and second portions separated from each other and formed with reverse symmetry. The first and second portions of the etch stopper may include horseshoe-shapes, the first and second portions of the driving output electrode may respectively overlap inner portions of the first and second portions of the etch stopper, and the first and second portions of the driving input electrode may respectively overlap outer portions of the first and second portions of the etch stopper. The organic light emitting device may further include a plurality of first electrodes, and the first and second portions of the driving output electrode may be respectively connected to a same first electrode.

The first and second semiconductors may have different crystalline structures. The first semiconductor may be made of amorphous silicon (“a-Si”), and the second semiconductor may be made of polycrystalline silicon or microcrystalline silicon.

The first and second semiconductors may be made of polycrystalline silicon or microcrystalline silicon.

The switching TFT may further include a switching control electrode connected to the first signal line under the first semiconductor and insulated from the first semiconductor, a switching input electrode connected to the second signal line and overlapping the first semiconductor, and a switching output electrode connected to the driving control electrode and facing the switching input electrode on the first semiconductor. The switching control electrode may be made with a same layer as the driving input electrode and the driving output electrode, and the switching input electrode and the switching output electrode may be made with a same layer as the driving control electrode. The switching control electrode and the driving control electrode may be formed on an insulating layer covering the driving input electrode and the driving output electrode.

The driving input electrode, the driving output electrode, the switching input electrode, and the switching output electrode may be made with a same layer. The switching control electrode and the driving control electrode may be made with a same layer. The organic light emitting device may further include a connecting member connecting the driving control electrode to the switching output electrode and that is made of a same layer as the first electrode.

The switching control electrode and the driving control electrode, the driving input electrode and the driving output electrode, and the switching input electrode and the switching output electrode may be made with different layers.

Overlapping portions between the etch stopper and the driving input and driving output electrodes may be compensated to each other when misaligned from each other to substantially uniformly maintain characteristics of the driving TFT.

In other exemplary embodiments of the present invention, a method for manufacturing an organic light emitting device is provided, which includes forming a switching semiconductor and a driving semiconductor on a substrate, respectively forming etch stoppers on the switching and driving semiconductors, forming a driving voltage line including a driving input electrode, a driving output electrode, a data line including a switching input electrode, and a switching output electrode, forming a gate insulating layer covering the driving voltage line, the driving output electrode, the data line, and the switching output electrode, forming a gate line including a switching control electrode and a driving control electrode, and forming a pixel electrode connected to the driving output electrode and a connecting member connecting the switching output electrode to the driving control electrode.

Forming the driving semiconductor may include forming first and second spaced portions of the driving semiconductor on the substrate, and forming a driving output electrode may include forming first and second portions surrounding and spaced from opposite ends of the driving input electrode and a connection connecting the first and second portions of the driving output electrode to each other.

In still other exemplary embodiments of the present invention, a method for manufacturing an organic light emitting device is provided, which includes forming a driving semiconductor on a substrate, forming an etch stopper on the driving semiconductor, forming a driving input electrode, a driving output electrode, and a gate line including a switching control electrode, forming a gate insulating layer covering the gate line, the driving output electrode, and the driving output electrode, forming a switching semiconductor on the gate insulating layer, forming a driving voltage line, a data line including a switching input electrode, and a driving control electrode, and forming a pixel electrode connected to the driving output electrode and a connecting member connecting the driving voltage line to the driving input electrode.

In yet other exemplary embodiments of the present invention, a method for manufacturing an organic light emitting device is provided, which includes forming a driving semiconductor on a substrate, forming an etch stopper on the driving semiconductor, forming a driving voltage line including a driving input electrode, and a driving output electrode, forming an interlayer insulating layer covering the driving voltage line and the driving output electrode, forming a gate line including a switching control electrode and a driving control electrode on the interlayer insulating layer, forming a gate insulating layer covering the gate line and the driving control electrode, forming a switching semiconductor on the gate insulating layer, forming a data line including a switching input electrode, and a switching output electrode, and forming a pixel electrode connected to the driving output electrode, and a connecting member connecting the switching output electrode to the driving control electrode.

In still yet other exemplary embodiments of the present invention, an organic light emitting device is provided, which includes a substrate, first and second signal lines formed on the substrate, a switching TFT connected to the first and second signal lines and including a first semiconductor, a driving TFT including a second semiconductor, an etch stopper formed on the second semiconductor, driving input and driving output electrodes overlapping the etch stopper and the second semiconductor and being opposite to each other with respect to the etch stopper, and a driving control electrode connected to the switching TFT and overlapping the second semiconductor, a first electrode connected to the driving output electrode, a second electrode opposite to the first electrode, and an organic light emitting member, wherein at least one of the etch stopper, the driving input electrode, and the driving output electrode has rotation symmetry with respect to a vertical or horizontal central line.

The overlapping portions between the etch stopper and the driving input electrode and the driving output electrode may include a donut shape. The overlapping portion between the etch stopper and the driving output electrode may be disposed in an overlapping portion between the etch stopper and the driving input electrode.

Alternatively, the overlapping portions between the etch stopper and the driving input electrode and driving output electrode may include an “S” shape. The driving input electrode may be a curved driving input electrode, and the driving output electrode may include two portions enclosed by the curved driving input electrode.

The first and the second semiconductors may have different crystalline structures. The first semiconductor may be made of a-Si, and the second semiconductor may be made of polycrystalline silicon or microcrystalline silicon.

The switching TFT may further include a switching control electrode connected to the first signal line under the first semiconductor and insulated from the first semiconductor, a switching input electrode connected to the second signal line and overlapping the first semiconductor, and a switching output electrode connected to the driving control electrode and facing the switching input electrode on the first semiconductor. A gate insulating layer may cover the driving input electrode, the driving output electrode, and the etch stopper. The driving input electrode, the driving output electrode, and the switching control electrode may be made with a same layer. The switching input electrode, the switching output electrode, and the driving control electrode may be made with a same layer.

### BRIEF DESCRIPTION OF THE DRAWINGS

The above and other features and advantages of the present invention will become more apparent by describing exemplary embodiments thereof in detail with reference to the accompanying drawings, in which:

FIG. 1 is an equivalent circuit diagram of an exemplary organic light emitting device according to an exemplary embodiment of the present invention;

FIG. 2 is an exemplary layout view of the exemplary organic light emitting device according to an exemplary embodiment of the present invention;

FIG. 3 is a sectional view of the exemplary organic light emitting device shown in FIG. 2, taken along line III-III;

FIGS. 4, 6, 8, 10, 12, and 14 are layout views of the exemplary organic light emitting device shown in FIGS. 2 and 3 in intermediate steps of an exemplary manufacturing method thereof according to an exemplary embodiment of the present invention;

FIGS. 5, 7, 9, 11, 13, and 15 are sectional views of the exemplary organic light emitting device shown in FIGS. 4, 6, 8, 10, 12, and 14 taken along lines V-V, VII-VII, IX-Ix, XI-XI, XIII-XIII, and XV-XV, respectively;

FIG. 16 is an exemplary layout view of an exemplary organic light emitting device according to another exemplary embodiment of the present invention;

FIG. 17 is a sectional view of the exemplary organic light emitting device shown in FIG. 16, taken along line XVII-XVII;

FIGS. 18, 20, 22, 24, 26, 28 and 30 are layout views of the exemplary organic light emitting device shown in FIGS. 16 and 17 in intermediate steps of an exemplary manufacturing method thereof according to an exemplary embodiment of the present invention;

FIGS. 19, 21, 23, 25, 27, 29, and 31 are sectional views of the exemplary organic light emitting device shown in FIGS. 18, 20, 22, 24, 26, 28, and 30 taken along lines XIX-XIX, XXI-XXI, XXIII-XXIII, XXV-XXV, XXVII-XXVII, XXIX-XXIX, and XXXI-XXXI, respectively;

FIG. 32 is an exemplary layout view of an exemplary organic light emitting device according to another exemplary embodiment of the present invention;

FIG. 33 is a sectional view of the exemplary organic light emitting device shown in FIG. 32, taken along line XXXIII-XXXIII;

FIGS. 34, 36, 38, 40, 42, 44, 46, and 48 are layout views of the exemplary organic light emitting device shown in FIGS. 32 and 33 in intermediate steps of an exemplary manufacturing method thereof according to an exemplary embodiment of the present invention;

FIGS. 35, 37, 39, 41, 43, 45, 47, and 49 are sectional views of the exemplary organic light emitting device shown in FIGS. 34, 36, 38, 40, 42, 44, 46, and 48 taken along lines XXXV-XXXV, XXXVII-XXXVII, XXXIX-XXXIX, XLI-XLI, XLIII-XLIII, XLV-XLV, XLVII-XLVII, and XLIX-XLIX, respectively;

FIG. 50 is an exemplary layout view of an exemplary driving thin film transistor (“TFT”) in an organic light emitting device according to another exemplary embodiment of the present invention;

FIG. 51 is an exemplary layout view of an exemplary driving TFT in an exemplary organic light emitting device according to another embodiment of the present invention;

FIG. 52 is an exemplary layout view of an exemplary organic light emitting device according to another exemplary embodiment of the present invention;

FIG. 53 is an enlarged layout view showing the exemplary driving TFT in the exemplary organic light emitting device shown in FIG. 52;

FIG. 54 is a sectional view of the exemplary organic light emitting device shown in FIG. 52, taken along line LIV-LIV;

FIGS. 55 to 61 are sectional views of the exemplary organic light emitting device shown in FIGS. 52 to 54 in intermediate steps of an exemplary manufacturing method thereof according to an exemplary embodiment of the present invention; and

FIG. 62 is an exemplary layout view of the exemplary organic light emitting device according to another exemplary embodiment of the present invention.

### DETAILED DESCRIPTION OF THE INVENTION

The present invention will be described more fully hereinafter with reference to the accompanying drawings, in which exemplary embodiments of the invention are shown. The present invention, may, however, be embodied in many different forms and should not be construed as limited to the embodiments set forth herein.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

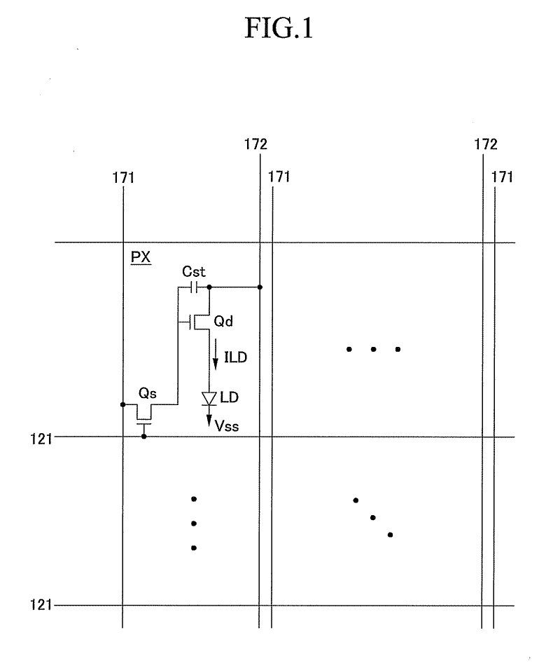

Now, an organic light emitting device according to an exemplary embodiment of the present invention will be described in detail with reference to FIG. 1.

FIG. 1 is an equivalent circuit diagram of an exemplary pixel of an exemplary organic light emitting device according to an exemplary embodiment of the present invention.

Referring to FIG. 1, an organic light emitting device display according to an exemplary embodiment of the present invention includes a plurality of signal lines 121, 171, and 172, and a plurality of pixels P connected thereto and arranged substantially in a matrix.

The signal lines include a plurality of gate lines 121 for transmitting gate signals (or scanning signals), a plurality of data lines 171 for transmitting data signals, and a plurality of driving voltage lines 172 for transmitting a driving voltage. The gate lines 121 extend substantially in a row direction, such as a first direction, and substantially parallel to each other, while the data lines 171 and the driving voltage lines 172 extend substantially in a column direction, such as a second direction, and substantially parallel to each other. The first direction may be substantially perpendicular to the second direction.

Each pixel P includes a switching transistor Qs, a driving transistor Qd, a capacitor Cst, and an organic light emitting diode (“OLED”) LD.

The switching transistor Qs has a control terminal, such as a gate electrode, connected to one of the gate lines 121, an input terminal, such as a source electrode, connected to one of the data lines 171, and an output terminal, such as a drain electrode, connected to the driving transistor Qd. The switching transistor Qs transmits the data signals applied to the data line 171 to the driving transistor Qd in response to the gate signal applied to the gate line 121.

The driving transistor Qd has a control terminal, such as a gate electrode, connected to the switching transistor Qs, an input terminal, such as a source electrode, connected to the driving voltage line 172, and an output terminal, such as a drain electrode, connected to the OLED LD. The driving transistor Qd drives an output current ILD having a magnitude depending on the voltage between the control terminal and the output terminal thereof.

The capacitor Cst is connected between the control terminal and the output terminal of the driving transistor Qd. The capacitor Cst stores the data signal applied to the control terminal of the driving transistor Qd and maintains the data signal after the switching transistor Qd turns off.

The OLED LD has an anode connected to the output terminal of the driving transistor Qd and a cathode connected to a common voltage Vss. The OLED LD emits light having an intensity depending on an output current ILD of the driving transistor Qd, thereby displaying images.

The switching transistor Qs and the driving transistor Qd are n-channel field effect transistors (“FETs”). However, at least one of the switching transistor Qs and the driving transistor Qd may be a p-channel FET. In addition, while a particular arrangement has been described, in alternative exemplary embodiments, the connections among the transistors Qs and Qd, the capacitor Cst, and the OLED LD may be modified.

### EMBODIMENT 1

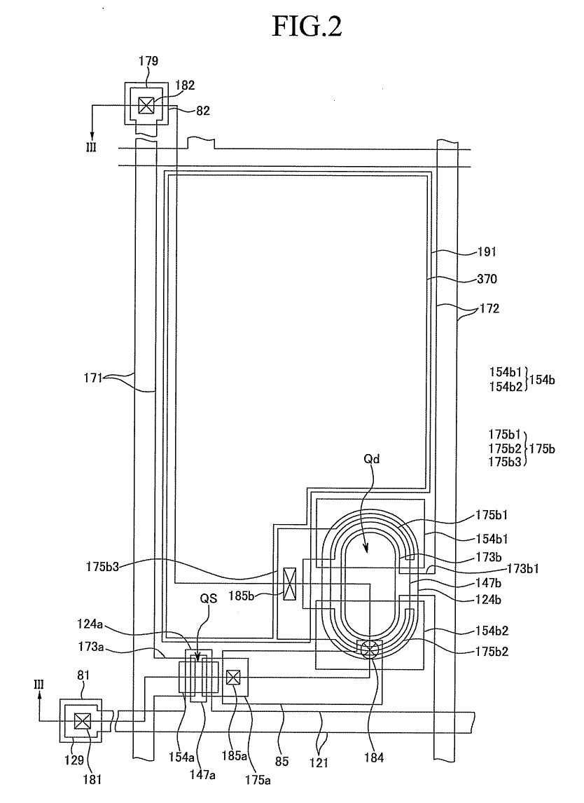

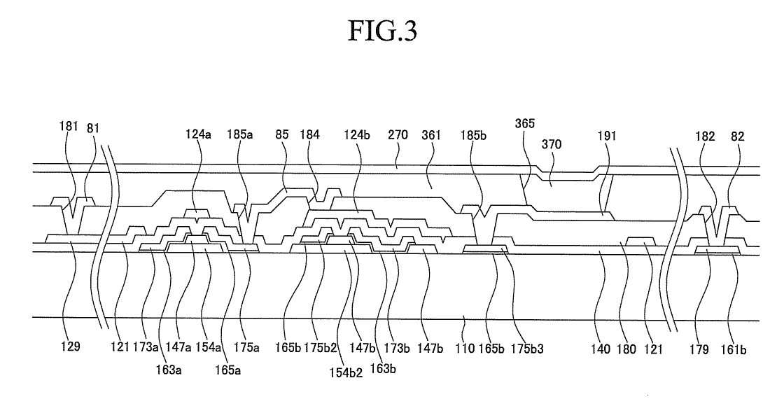

Referring to FIGS. 2 and 3, a detailed structure of the organic light emitting device shown in FIG. 1 according to an exemplary embodiment of the present invention will be described in detail.

FIG. 2 is a schematic plan view of an exemplary organic light emitting device according to an exemplary embodiment of the present invention, and FIG. 3 is a sectional view of the exemplary organic light emitting device shown in FIG. 2 taken along line II-II.

A plurality of switching and driving semiconductor islands 154a and 154b preferably made of microcrystalline silicon or polycrystalline silicon are formed on an insulating substrate 110 made of a material such as, but not limited to, transparent glass, quartz, or sapphire.

The switching and driving semiconductor islands 154a and 154b are separated from each other, and the driving semiconductor islands 154b include a first portion 154b1 and a second portion 154b2 that are separated from each other and are disposed in the vertical direction. In other words, the first portion 154b1 and the second portion 154b2 are disposed in an extending direction of data lines 171 and driving voltage lines 172, as will be further described below.

A plurality of etch stoppers 147a and 147b preferably made of insulating material such as silicon nitride or silicon oxide are respectively formed on the center portions of the switching and driving semiconductor islands 154a and 154b.

Each etch stopper 147b includes two semi-circular portions that are disposed with a predetermined distance therebetween, and two linear portions connecting the two semi-circular portions and having an opening. In other words, the etch stopper 147b includes an oval ring shape. The upper and the lower portions of the etch stoppers 147b respectively overlap the first and second portions 154b1 and 154b2 of the driving semiconductor islands 154b, and the etch stoppers 147b have reverse symmetry in the vertical and horizontal directions.

A plurality of data lines 171, a plurality of driving voltage lines 172, and a plurality of switching and driving output electrodes 175a and 175b are formed on the etch stoppers 147a and 147b and on the switching and driving semiconductor islands 154a and 154b, as well as on the insulating substrate 110.

The data lines 171 for transmitting data signals extend substantially in the longitudinal direction, such as the second direction. Each data line 171 includes a plurality of switching input electrodes 173a extending to and partially overlapping the switching semiconductor islands 154a and an end portion 179 having a large area for contact with another layer or an external driving circuit. The data lines 171 may extend to be directly connected to a data driving circuit (not shown) for generating the data signals, which may be integrated with the substrate 110.

The switching output electrodes 175a are separated from the data lines 171 and the driving voltage lines 172. The switching output electrodes 175a partially overlap the switching semiconductor islands 154a. Each of a pair of a switching input electrode 173a and a switching output electrode 175a are disposed opposite each other with respect to the switching semiconductor islands 154a.

The driving voltage lines 172 for transmitting driving voltages extend substantially in the longitudinal direction, such as the second direction, and substantially parallel to the data lines 171. Each driving voltage line 172 includes a plurality of bridges 173b1 and a plurality of driving input electrodes 173b overlapping the driving semiconductor islands 154b and connected to the bridges 173b1. The bridges 173b1 may extend between the first and second portions 154b1 and 154b2 of the driving semiconductor islands 154b. Here, the driving input electrodes 173b have shapes of a running oval that are set in the longitudinal direction. The central portions of the driving input electrodes 173b overlap the openings of the etch stoppers 147b, and the edge portions of the driving input electrodes 173b overlap the inner portions of the etch stoppers 147b. Accordingly, the border lines of the driving input electrodes 173b are disposed on the etch stoppers 147b overlapping thereof and the driving input electrodes 173b are connected to the driving voltage lines 172 through the bridges 173b1. Also, the driving input electrodes 173b have reverse symmetry with respect to the vertical lines and horizontal lines.

Each driving output electrode 175b that is separated from the data line 171 and the driving voltage line 172 includes a first portion 175b1, a second portion 175b2, and a connection 175b3 connecting the first and second portions 175b1 and 175b2 to each other. The first portions 175b1 and the second portions 175b2 of the driving output electrodes 175b are respectively opposite to, but not connected to, the upper portions and the lower portions of the driving input electrodes 173b with respect to the upper and lower portions of the etch stoppers 147b that respectively overlap the first and second portions 154b1 and 154b2 of the driving semiconductor islands 154b. The inner boundary lines of the first and second portions 175b1 and 175b2 of the driving output electrodes 175b are disposed on the etch stoppers 147b, such that the first and second portions 175b1 and 175b2 of the driving output electrodes 175b overlap the portions of the etch stoppers 147b. The first and second portions 175b1 and 175b2 of the driving output electrodes 175b have reverse symmetry to each other, and they also respectively have reverse symmetry with respect to a vertical central line thereof. The connections 175b3 of the driving output electrodes 175b to connect the first and second portions 175b1 and 175b2 have a wide area and are disposed, in relation to FIG. 2, at the left side of the first and second portions 175b1 and 175b2. That is, the first and second portions 175b1 and 175b2 of the driving output electrode 175b are disposed between the driving voltage line 172 and the connection 175b3 for each pixel.

The data lines 171 including the switching input electrodes 173a and the end portions 179, the driving voltage lines 172 including the driving input electrodes 173b, and the switching and driving output electrodes 175a and 175b may have inclined edge profiles, and the inclination angles thereof range from about 30 to about 80 degrees.

A plurality of pairs of ohmic contacts 163b and 165b are respectively formed between the semiconductor islands 154b and the driving input and driving output electrodes, respectively. The ohmic contacts 163b and 165b have substantially the same planar shapes as the driving input and driving output electrodes 173b and 175b, respectively. The ohmic contacts 163b and 165b are preferably made of silicide or n+ hydrogenated amorphous silicon (“a-Si”) heavily doped with an n-type impurity such as phosphorous. The ohmic contacts (not shown) may also be disposed under the driving voltage lines 172 with the same planar shapes as the driving voltage lines 172.

Furthermore, a plurality of pairs of ohmic contacts 163a and 165a are respectively formed under the switching input and switching output electrodes 173a and 175a, respectively. The ohmic contacts 163a and 165a have substantially the same planar shapes as the switching input and switching output electrodes 173a and 175a, respectively. The ohmic contacts may also be disposed under the data lines 171 with the same planar shapes as the data lines 171, such as shown by ohmic contact 161b under end portion 179 of data line 171.

A gate insulating layer 140 preferably made of silicon nitride (SiNx) or silicon oxide (SiOx) is formed on the data lines 171, the driving voltage lines 172, and the switching and driving output electrodes 175a and 175b, as well as on exposed surfaces of the insulating substrate 110 and the etch stoppers 147a, 147b.

A plurality of gate lines 121 and a plurality of driving control electrodes 124b are formed on the gate insulating layer 140.

The gate lines 121 for transmitting gate signals extend substantially in a transverse direction, such as the first direction, and intersect the data lines 171 and the driving voltage lines 172. Each gate line 121 further includes an end portion 129 having a large area for contact with another layer or an external driving circuit, and switching control electrodes 124a projecting upward from the gate line 121 and overlapping the switching semiconductor islands 154a between the switching input electrodes 173a and switching output electrodes 175a. The gate lines 121 may extend to be directly connected to a gate driving circuit (not shown) for generating the gate signals, which may be integrated with the substrate 110.

Each of the driving control electrodes 124b is separated from the gate lines 121 and has the running oval shape. The driving control electrodes 124b overlap the first and second portions 154b1, 154b2, 175b1, and 175b2 of the driving semiconductor islands 154b and the driving output electrodes 175b, respectively, and the central portions of the driving control electrodes 124b overlap the openings of the etch stoppers 147b and the driving input electrodes 173b.

The lateral sides of the gate lines 121 and the driving control electrodes 124b are inclined relative to a surface of the substrate 110, and the inclination angle thereof ranges from about 30 to about 80 degrees.

A passivation layer 180 is formed on the gate lines 121 and the driving control electrodes 124b, as well as on exposed surfaces of the gate insulating layer 140.

The passivation layer 180 and the gate insulating layer 140 have a plurality of contact holes 185a, 185b, and 182 exposing the switching output electrodes 175a, the connections 175b3 of the driving output electrodes 175b, and the end portions 179 of the data lines 171, respectively, and the passivation layer 180 has a plurality of contact holes 181 and 184 exposing the driving control electrodes 124b and the end portions 129.

A plurality of pixel electrodes 191, a plurality of connecting members 85, and a plurality of contact assistants 81 and 82 are formed on the passivation layer 180.

The pixel electrodes 191 are connected to the switching output electrodes 175b through the contact holes 185b.

The connecting members 85 are connected to the driving control electrodes 124b and the switching output electrodes 175a through the contact holes 184 and 185a, respectively.

The contact assistants 81 and 82 are connected to the end portions 129 of the gate lines 121 and the end portions 179 of the data lines 171 through the contact holes 181 and 182, respectively, and they protect the end portions 129 and 179 and enhance the adhesion between the end portions 129 and 179 and external devices.

The pixel electrodes 191, the connecting members 85, and the contact assistants 81 and 82 may be made of a transparent conductor such as indium tin oxide (“ITO”) or indium zinc oxide (“IZO”), and they may be made of an opaque conductor such as aluminum Al or an alloy thereof, or of gold Au, platinum Pt, nickel Ni, copper Cu, or tungsten W having a large work function or an alloy thereof in a top emission type.

A partition 361 is formed on the pixel electrodes 191, the connecting members 85, and the contact assistants 81 and 82. The partition 361 surrounds the pixel electrodes 191 like a bank to define openings 365. The partition 361 may be made of organic insulators such as acrylic resin and polyimide resin having heat-resistant and dissolvent properties, or inorganic insulators such as silicon dioxide (SiO₂) and titanium dioxide (TiO₂), and may have a multilayered structure. The partition 361 may be made of a photosensitive material containing black pigment so that the black partition 361 may serve as a light blocking member and the formation of the partition 361 may be simplified.

A plurality of light emitting members 370 are formed on the pixel electrodes 191 and confined in the openings 365 defined by the partition 361.

Each of the light emitting members 370 may have a multilayered structure including an emitting layer (not shown) for emitting light and auxiliary layers (not shown) for improving the efficiency of light emission of the emitting layer.

The light emitting members 370 uniquely emitting light of one of color in a set of colors such as primary colors, and such as red, green, and blue are preferably respectively arranged in each pixel, and the light emitting members 370 emitting light of three colors such as red, green, and blue may all be arranged in one pixel with vertical or horizontal deposition to form a white emitting layer under or above the color filters emitting light of one of the colors such as red, green, and blue.

Here, the color filters may be disposed under the emitting layer in a bottom emission type, and the color filters may be disposed on the emitting layer in a top emission type.

Furthermore, the luminance can be improved by further including the white pixel (W) as well as the red, green, and blue pixels (R, G, B) with stripe or check arrangements.

A common electrode 270 is formed on the light emitting members 370 and the partition 361.

The common electrode 270 is formed on the whole of the substrate 110, or at least substantially the entire substrate 110, and supplies current to the light emitting members 370 in cooperation with the pixel electrodes 191.

In the above-described organic light emitting device, a switching control electrode 124a connected to a gate line 121, a switching input electrode 173a connected to a data line 171, and a switching output electrode 175a along with a semiconductor island 154a form a switching thin film transistor (“TFT”) Qs having a channel formed in the semiconductor island 154a disposed between the switching input electrode 173a and the switching output electrode 175a. Likewise, a driving control electrode 124b connected to a switching output electrode 175a, a driving input electrode 173b connected to a driving voltage line 172, and a driving output electrode 175b connected to a pixel electrode 191 along with a semiconductor island 154b form a driving TFT Qd having a channel formed in the semiconductor island 154b disposed between the driving input electrode 173b and the driving output electrode 175b.

Although the OLED display according to this embodiment includes a plurality of pixels having one switching TFT Qs and one driving TFT Qd, in alternative exemplary embodiments, other TFTs and wiring for driving them may be included to prevent the driving TFT Qd from degrading and the lifetime of the OLED display from being shortened.

A pixel electrode 191, a light emitting member 370, and the common electrode 270 form an OLED LD having the pixel electrode 191 as an anode and the common electrode 270 as a cathode, or vice versa. The overlapping portions of a storage electrode and a driving voltage line 172 form a storage capacitor Cst.

Although the OLED display according to this exemplary embodiment includes one driving TFT Qd connected to one side of the driving voltage lines 172, the driving TFT Qd may be connected to both sides of the driving voltage lines 172 with symmetry, and the driving voltage lines 172 may be divided into two. In this structure, one driving voltage line 172 may be arranged with respect to the neighboring two data lines 171, and the neighboring two pixel rows hold the same driving voltage lines 171 in common. The driving voltage lines 171 may be connected to the driving TFT Qd of the neighboring two pixel rows.

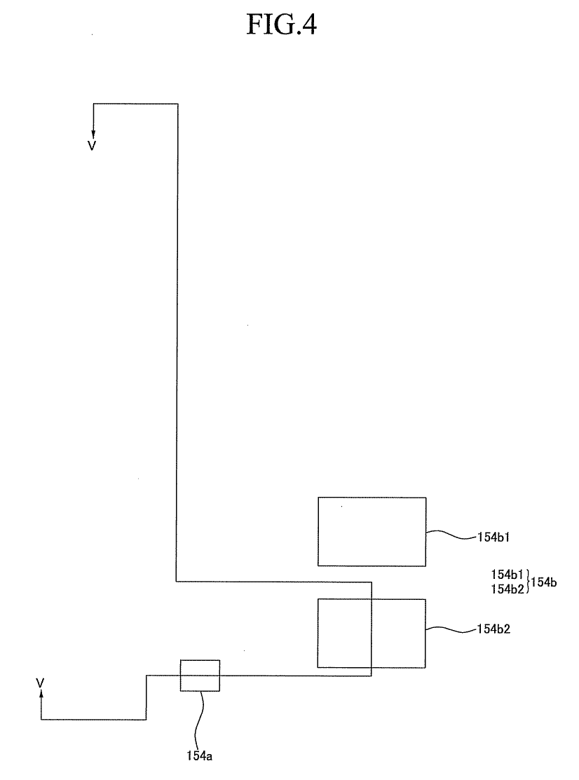

Now, an exemplary method of manufacturing the exemplary display panel shown in FIGS. 2 and 3 is described with reference to FIGS. 4 to 15 as well as FIGS. 2 and 3.

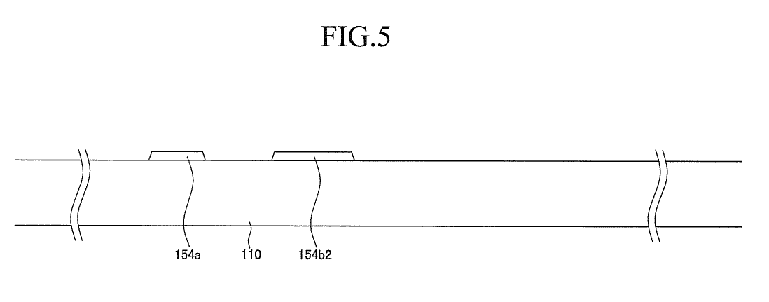

FIGS. 4, 6, 8, 10, 12 and 14 are layout views of the exemplary organic light emitting device shown in FIGS. 2 and 3 in intermediate steps of an exemplary manufacturing method thereof according to an exemplary embodiment of the present invention, and FIGS. 5, 7, 9, 11, 13 and 15 are sectional views of the exemplary organic light emitting device shown in FIGS. 4, 6, 8, 10, 12 and 14 taken along lines V-V, VII-VII, IX-IX, XI-XI, XIII-XIII, and XV-XV, respectively.

As shown in FIGS. 4 and 5, a-Si is deposited and then crystallized, or polycrystalline silicon is deposited on an insulating substrate 110 made of a material such as transparent glass, quartz, or sapphire to form a polycrystalline silicon layer.

Next, the polycrystalline silicon layer is patterned by photolithography to form a plurality of switching semiconductor islands 154a and a plurality of driving semiconductor islands 154b including first and second portions 154b1 and 154b2.

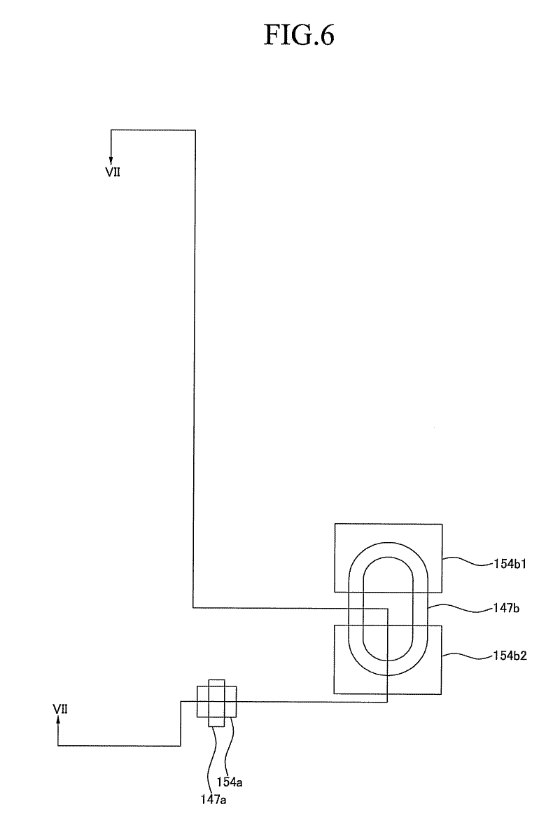

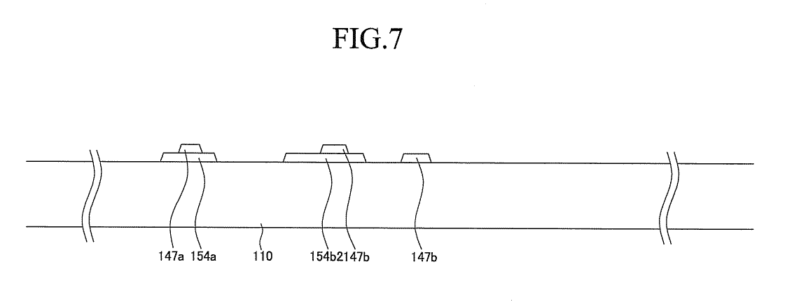

Next, as shown in FIGS. 6 and 7, an insulating layer made of silicon nitride or silicon oxide is deposited on the substrate 110, and patterned to form a plurality of etch stoppers 147a with a bar shape on the switching semiconductor islands 154a, and a plurality of etch stoppers 147b with a running oval shape on the driving semiconductor islands 154b. Thereafter, H2 plasma treatment is executed in order to stabilize the exposed surfaces of the switching and driving semiconductor islands 154a and 154b.

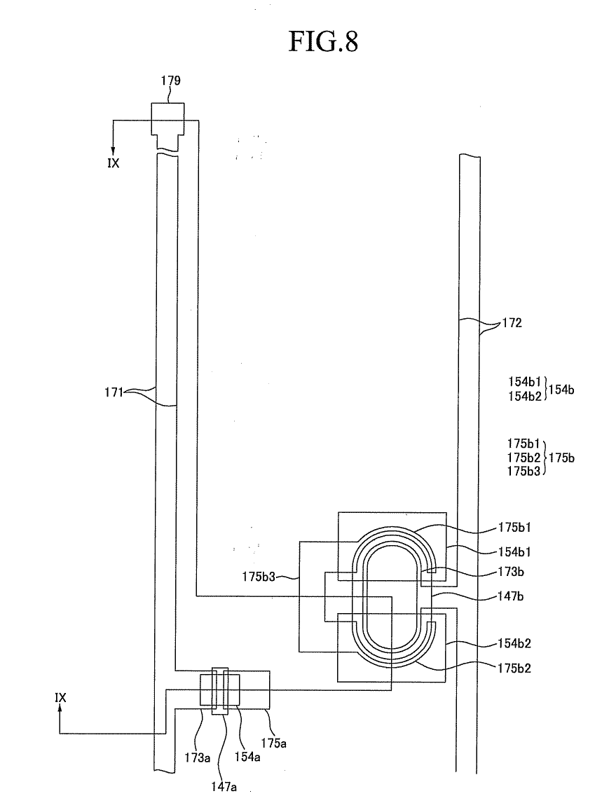

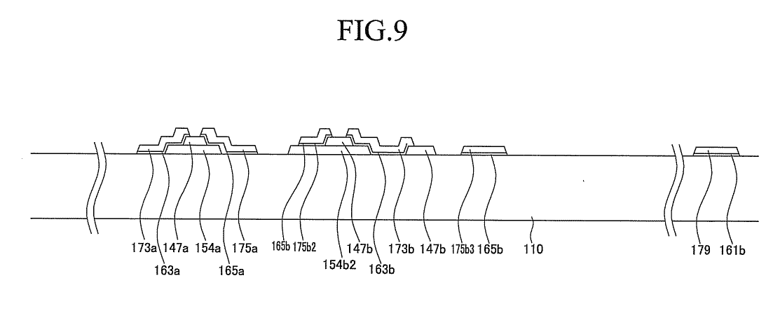

Then, as shown in FIGS. 8 and 9, an a-Si layer doped with impurities or a microcrystalline silicon layer, and a conductive layer, are sequentially deposited, and the conductive layer is patterned by photolithography to form a plurality of data lines 171 including switching input electrodes 173a and end portions 179, a plurality of switching output electrodes 175a, a plurality of driving voltage lines 172 including driving input electrodes 173b, and a plurality of driving output electrodes 175b. Next, the exposed silicon layer is removed to form a plurality of pairs of ohmic contacts 163a and 165a and a plurality of pairs of ohmic contacts 163b and 165b, respectively, as well as the ohmic contacts underlying the data lines 171 and driving voltage lines 172.

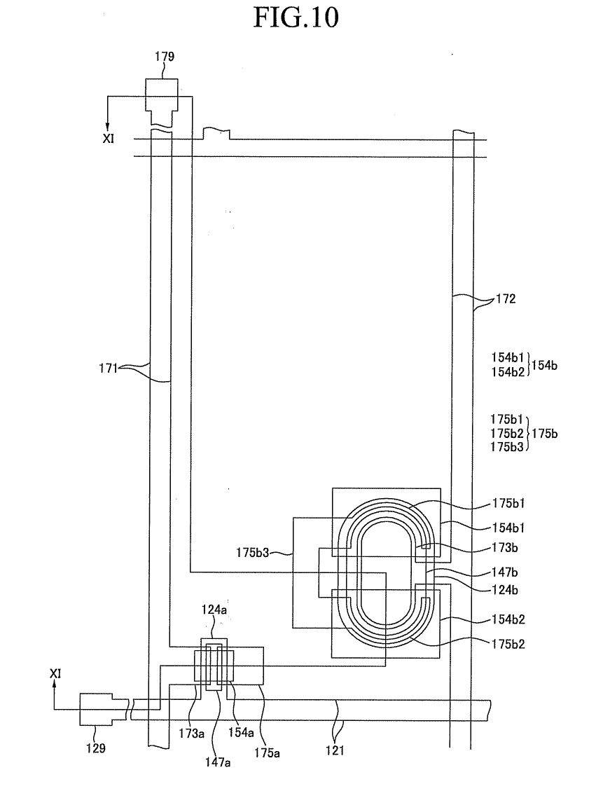

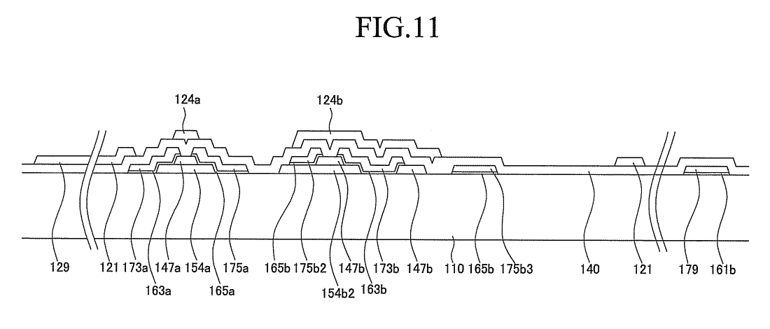

Next, as shown in FIGS. 10 to 11, a gate insulating layer 140 made of silicon nitride is formed on the data conductors 171, 172, 175a, and 175b, and on the exposed portions of the substrate 110, and a conductive layer is sputtered on the gate insulating layer and photo-etched to form a plurality of gate lines 121 including switching control electrodes 124a and end portions 129, and a plurality of driving control electrodes 124b.

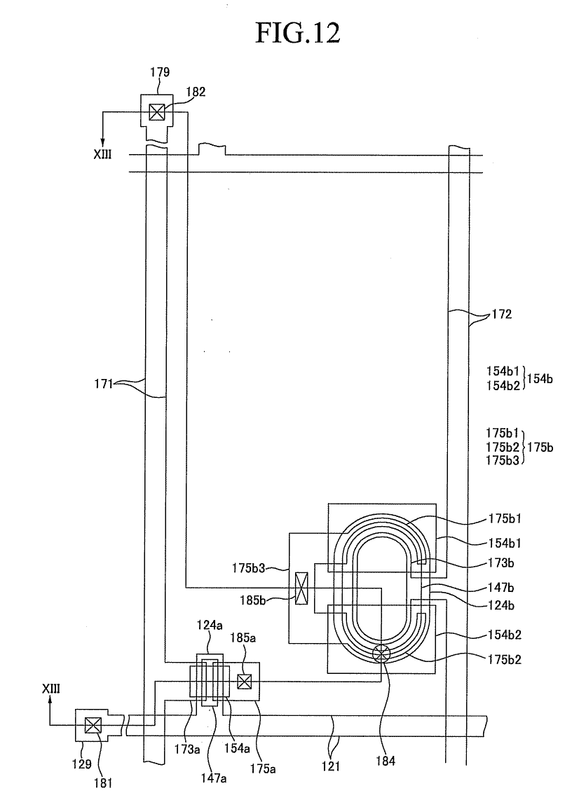

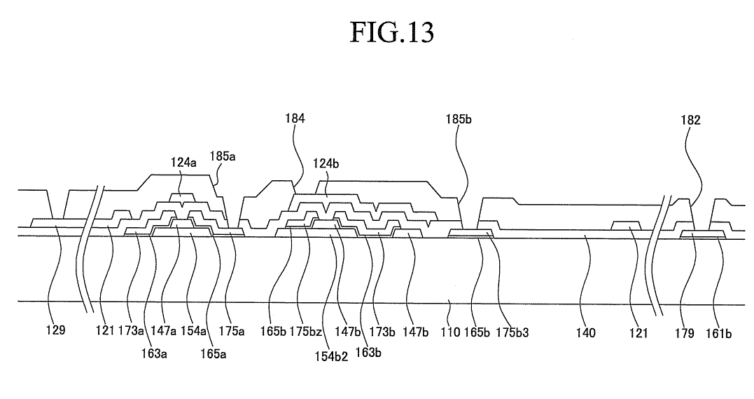

Referring to FIGS. 12 and 13, a passivation layer 180 is deposited by chemical vapor deposition (“CVD”), printing, etc., and patterned along with the gate insulating layer 140 to form a plurality of contact holes 181, 182, 184, 185a, and 185b.

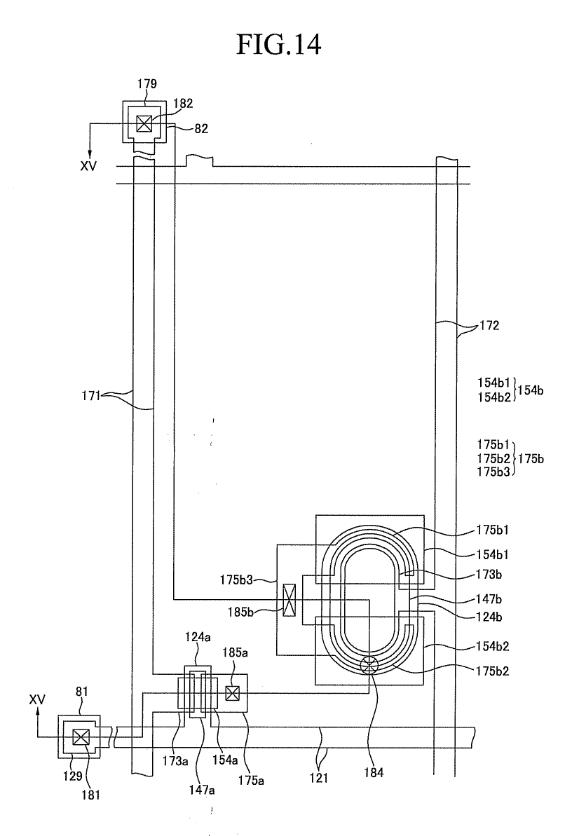

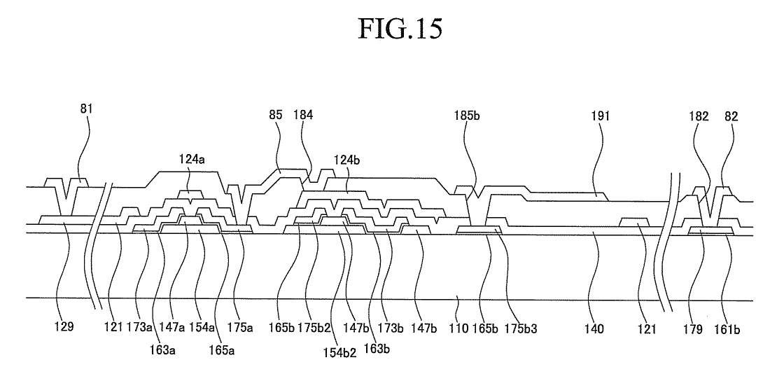

Next, as shown in FIGS. 14 and 15, a transparent conductive film is deposited on the passivation layer 180 by sputtering, etc., and it is photo-etched to form a plurality of pixel electrodes 191, a plurality of connecting members 85, and a plurality of contact assistants 81 and 82.

Referring again to FIGS. 2 and 3, a photosensitive organic insulator is spin-coated, and is exposed and developed to form a partition 361 having openings 365 partly exposing the pixel electrodes 191.

Next, a plurality of organic light emitting members 370 including an electron transport layer, a hole transport layer, and an emitting layer are formed on the pixel electrodes 191 in the openings 365.

Next, a common electrode 270 is formed on the organic light emitting members 370 and the partition 361.

In the exemplary manufacturing method of the exemplary organic light emitting device according to the present invention, the driving input electrodes 173b, the driving output electrodes 175b, and the etch stoppers 147b that overlap each other are respectively symmetrical with respect to the vertical or the horizontal central lines thereof. Therefore, even if the driving input electrodes 173b, the driving output electrodes 175b, and the etch stoppers 147b are misaligned during manufacture, the overlapping portions of the driving input electrodes 173b, the driving output electrodes 175b, and the etch stoppers 147b are compensated to each other, and the overlapping portions may be uniformly maintained. Accordingly, even if the misalignment is generated in the manufacturing process, the off-set regions where the driving voltage is blocked by the driving input and driving output electrodes 173b and 175b may be uniformly maintained such that the uniform characteristics of the driving TFTs may be obtained thereby improving the quality of the display device.

### EMBODIMENT 2

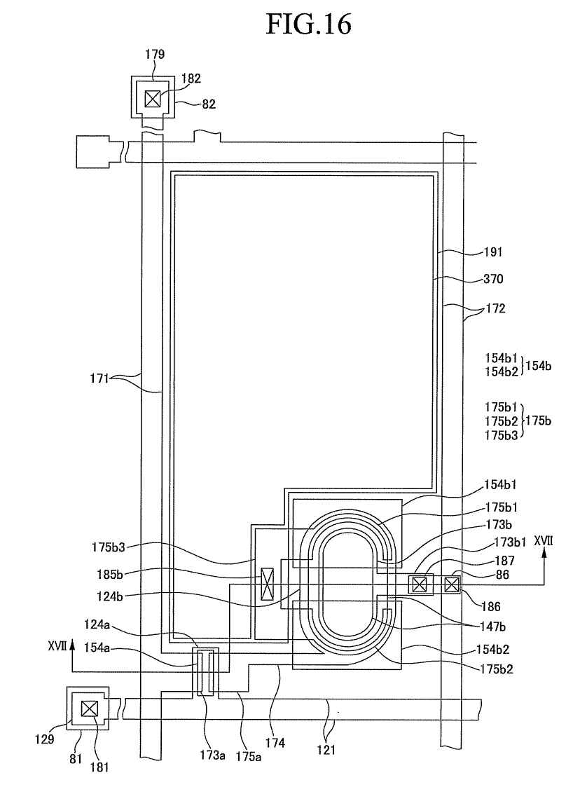

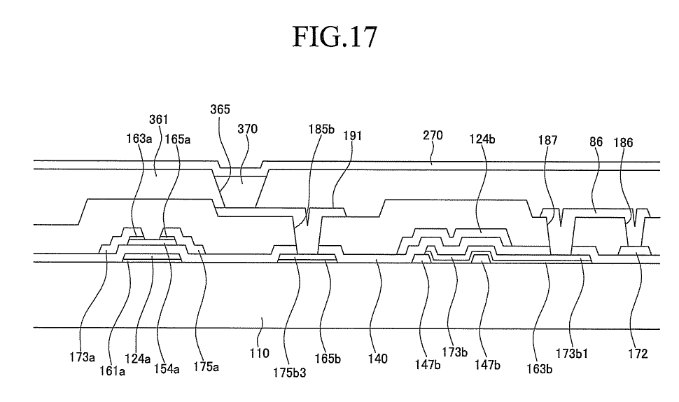

Referring to FIGS. 16 and 17, a detailed structure of an exemplary organic light emitting device shown in FIG. 1 according to another exemplary embodiment of the present invention will be described in detail.

FIG. 16 is an exemplary layout view of an exemplary organic light emitting device according to another exemplary embodiment of the present invention, and FIG. 17 is a sectional view of the exemplary organic light emitting device shown in FIG. 16, taken along line XVII-XVII. Detailed descriptions of elements having the same or substantially the same function as in the previous embodiments are omitted in this description of this embodiment according to the present invention for convenience of description.

A plurality of driving semiconductor islands 154b preferably made of crystalline silicon and including first and second portions 154b1 and 154b2 are formed on an insulating substrate 110, and a plurality of etch stoppers 147b preferably made of an insulating material and having a running oval shape are formed on the first and second portions 154b1 and 154b2 as well as on the insulating substrate 110.

A plurality of gate lines 121 including a switching control electrode 124a and an end portion 129, a plurality of driving input electrodes 173b, and a plurality of driving output electrodes 175b are formed on the substrate 110, the driving semiconductor islands 154b, and the etch stoppers 147b. The driving input electrodes 173b overlap the inner boundary of the etch stoppers 147b, and the driving output electrodes 175b include first and second portions 175b1 and 175b2 overlapping the etch stoppers 147b, and a connection 175b3 connecting the first and second portions 175b1 and 175b2 to each other.

A plurality of pairs of ohmic contacts 163b and 165b are respectively formed between the semiconductor islands 154b, and the driving input and driving output electrodes 175b and 173b, respectively. The ohmic contacts 161a are disposed under the gate lines 121 with the same planar shapes as the gate lines 121.

A gate insulating layer 140 is formed on the gate lines 121, the driving input electrodes 173b, the driving output electrodes 175b, and the driving semiconductor islands 154b, as well as on exposed surfaces of the insulating substrate 110.

A plurality of switching semiconductor islands 154a preferably made of a-Si and overlapping the switching control electrodes 124a are formed on the gate insulating layer 140.

A plurality of data lines 171 including switching input electrodes 173a and an end portion 179, a plurality of switching output electrodes 175a, a plurality of driving control electrodes 124b connected to the switching output electrodes 175a such as by connecting portions 174, and a plurality of driving voltage lines 172 are formed on the switching semiconductor islands 154a and the gate insulating layer 140. The driving input electrodes 173b have a plurality of bridges 173b1 extended toward the driving voltage lines 172.

A plurality of pairs of ohmic contacts 163a and 165a are respectively formed between the switching input and switching output electrodes 173a and 175a, and the switching semiconductor islands 154a, respectively.

A passivation layer 180 is formed on the data lines 171, the switching output electrodes 175a, the driving control electrodes 124b, and the driving voltage lines 172, as well as on exposed portions of the gate insulating layer 140.

The passivation layer 180 and the gate insulating layer 140 have a plurality of contact holes 181, 185b, and 187 exposing the connections 175b3 of the driving output electrodes 175b, the bridges 173b1 of the driving input electrodes 173b, and the end portions 129 of the gate lines 121, respectively, and the passivation layer 180 has a plurality of contact holes 186 and 182 exposing the portions of the driving voltage lines 172 adjacent to the driving input electrodes 173b and the end portions 179 of the data lines 171.

A plurality of pixel electrodes 191 connected to the driving output electrodes 175b, a plurality of connecting members 86 connecting the driving voltage lines 172 and the driving input electrodes 173b, and a plurality of contact assistants 81 and 82 respectively connected to the end portions 129 and 179 are formed on the passivation layer 180.

As described above, the switching semiconductor 154a of the organic light emitting device according to this embodiment is made of a-Si, while the driving semiconductor 155b of the organic light emitting device display according to this embodiment is made of microcrystalline silicon or polycrystalline silicon. Thus, the channel of the switching TFT Qs includes a-Si, while the channel of the driving TFT Qd includes microcrystalline silicon or polycrystalline silicon.

The driving TFT Qd may include a channel of microcrystalline silicon or polycrystalline silicon such that the driving TFT Qd may have carrier mobility and stability. Accordingly, the current flowing in the driving TFT Qd may increase to enhance luminance of the OLED according to the exemplary embodiments of the present invention. Also, the so-called threshold voltage shift phenomenon caused by applying a constant positive voltage in driving of an OLED may be excluded such that an image sticking phenomenon is not generated and the life-time reduction of the OLED does not occur.

Meanwhile, the channel of the switching TFT Qs includes a-Si having a low off current. Accordingly the on/off characteristic of the switching TFT Qs for controlling the data voltage, particularly reduction of the off current, may be maintained well such that the data voltage reduction due to a high off current may be prevented and the cross-talk phenomenon of the OLED may be reduced. If the channel of the switching TFT Qs included microcrystalline silicon or polycrystalline silicon, instead of a-Si, then the off current of the switching TFT Qs may be high to cause the data voltage to reduce and the cross-talk phenomenon of the OLED to occur.

As described above, the switching TFT Qs and the driving TFT Qd of the OLED display according to this embodiment have channels made of different materials such that the desired characteristics for the switching TFT and driving TFT may be satisfied.

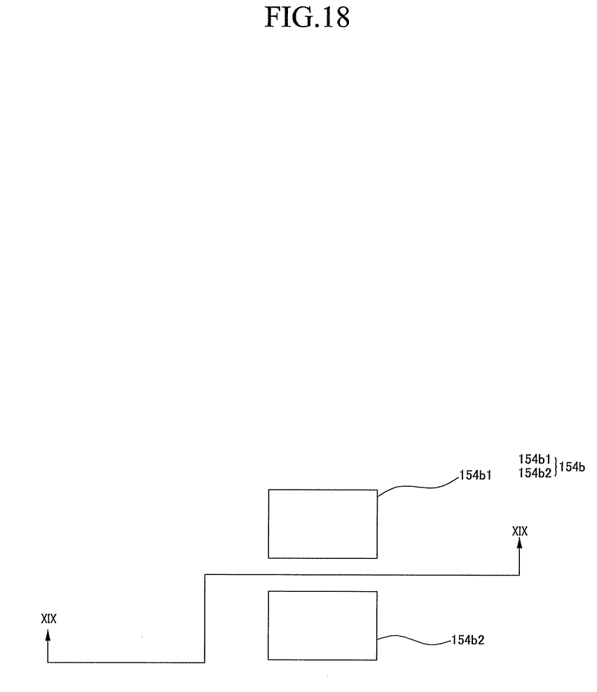

Now, an exemplary method of manufacturing the exemplary display panel shown in FIGS. 16 and 17 is described with reference to FIGS. 18 to 31 as well as FIGS. 16 and 17.

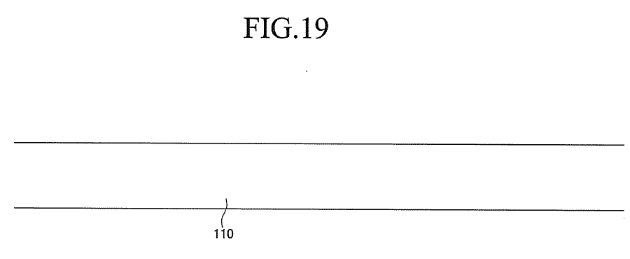

FIGS. 18, 20, 22, 24, 26, 28, and 30 are layout views of the exemplary organic light emitting device shown in FIGS. 16 and 17 in intermediate steps of an exemplary manufacturing method thereof according to an exemplary embodiment of the present invention, and FIGS. 19, 21, 23, 25, 27, 29, and 31 are sectional views of the exemplary organic light emitting device shown in FIGS. 18, 20, 22, 24, 26, 28, and 30 taken along lines XIX-XIX, XXI-XXI, XXIII-XXIII, XXV-XXV, XXVII-XXVII, XXIX-XXIX, and XXXI-XXXI, respectively.

As shown in FIGS. 18 and 19, a-Si is deposited and then crystallized, or polycrystalline silicon is deposited on an insulating substrate 110 to form a polycrystalline silicon layer.

Next, the polycrystalline silicon layer is patterned by photolithography to form a plurality of driving semiconductor islands 154b.

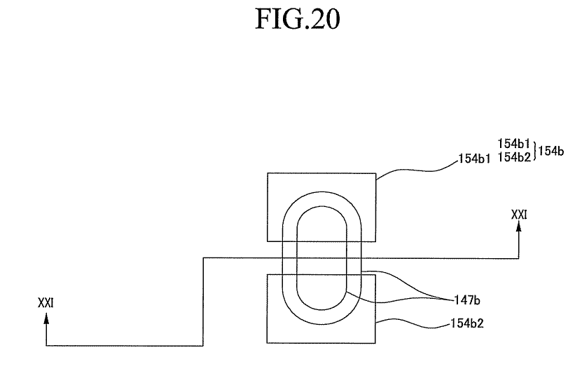

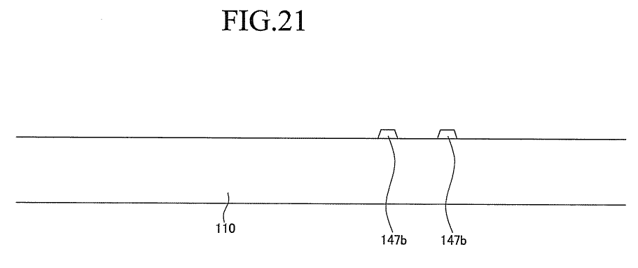

Next, as shown in FIGS. 20 and 21, a insulating layer is deposited on the substrate 110, and patterned to form a plurality of etch stoppers 147b with a running oval shape on the driving semiconductor islands 154b and the substrate 110.

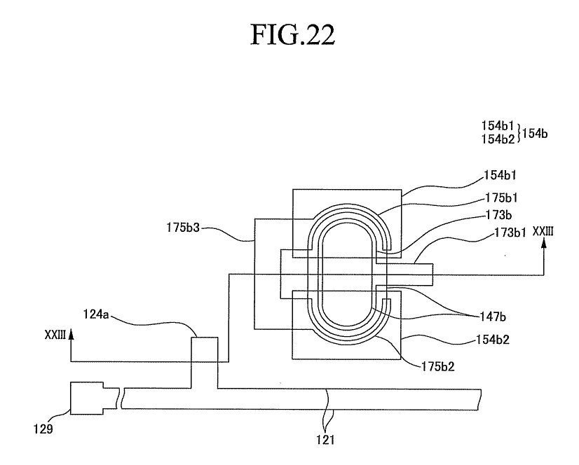

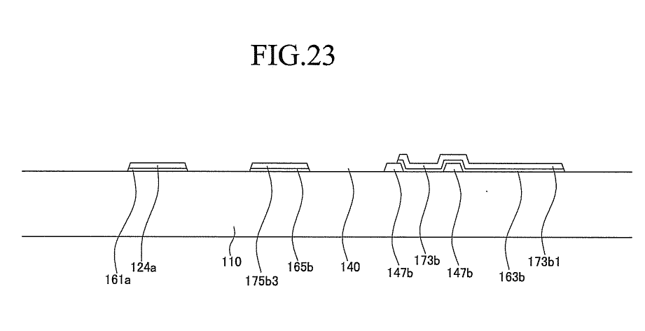

Then, as shown in FIGS. 22 and 23, an a-Si layer doped with impurities or a microcrystalline silicon layer, and a conductive layer, are sequentially deposited, and the conductive layer is patterned by photolithography to form a plurality of gate lines 121 including switching control electrodes 124a and end portions 129, a plurality of driving input electrodes 173b, and a plurality of driving output electrodes 175b. Next, the exposed silicon layer is removed to form a plurality of pairs of ohmic contacts 163b and 165b, respectively. Also, an ohmic contact layer 161a may be formed under the gate lines 121.

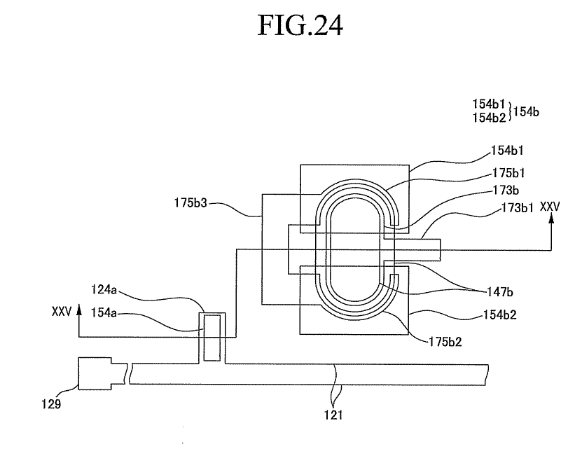

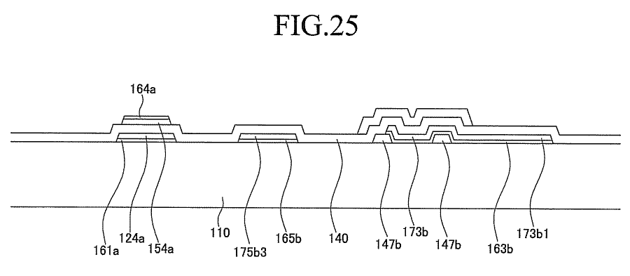

Next, as shown in FIGS. 24 to 25, a gate insulating layer 140 made of silicon nitride, an intrinsic silicon layer, and an extrinsic silicon layer are sequentially formed on the gate lines 121, the driving input electrodes 173b, and the driving output electrode 175b, and on exposed portions of the substrate 110, and the intrinsic silicon layer and the extrinsic silicon layer are photo-etched to form a plurality of switching semiconductor islands 154a and a plurality of ohmic contact layers 164a on the gate insulating layer 140.

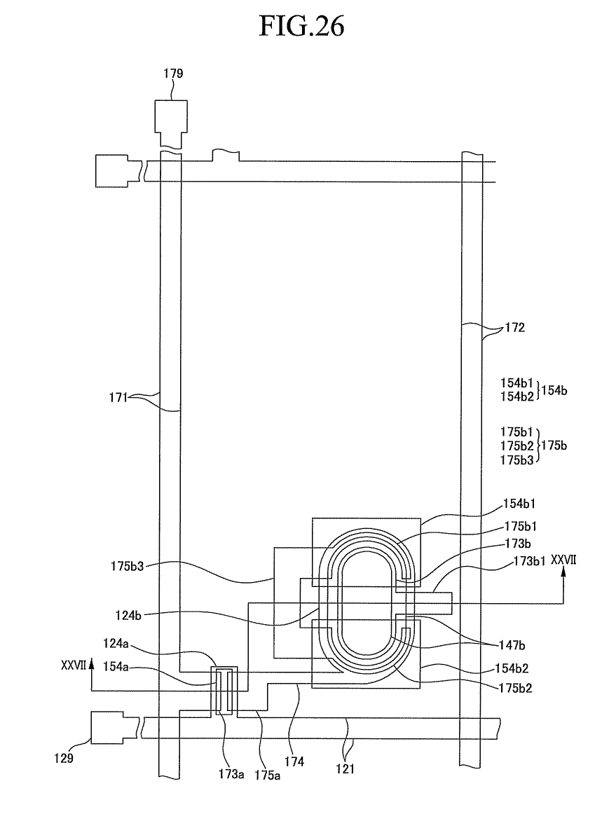

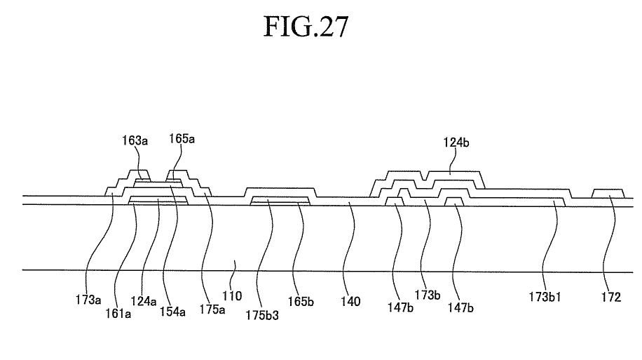

Next, as shown in FIGS. 26 to 27, a conductive layer is deposited on the switching semiconductor islands 154a, the ohmic contact layers 164a, and the gate insulating layer 140, and the conductive layer is patterned by photolithography to form a plurality of data lines 171 including switching input electrodes 173a and end portions 179, a plurality of switching output electrodes 175a, a plurality of driving voltage lines 172, and a plurality of driving control electrodes 124b connected to the switching output electrodes 175a, such as by connecting portions 174. Next, the exposed portions of the ohmic contact layers 164a are removed to form a plurality of pairs of ohmic contacts 163a and 165a, respectively.

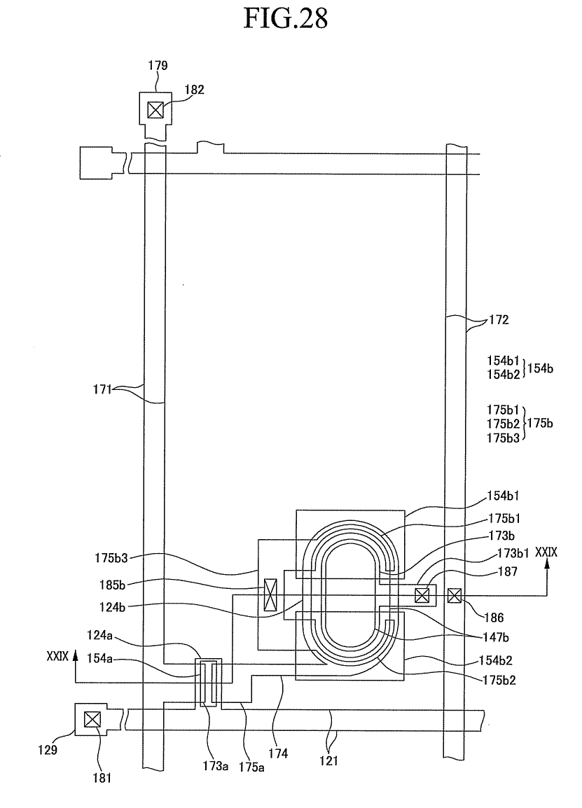

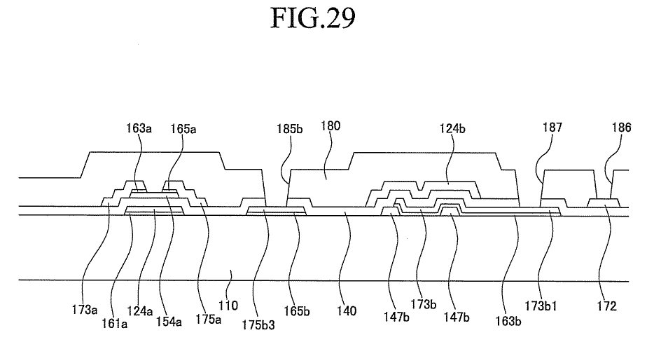

Referring to FIGS. 28 and 29, a passivation layer 180 is deposited by CVD, printing, etc., and patterned along with the gate insulating layer 140 to form a plurality of contact holes 181, 182, 186, 187, and 185b.

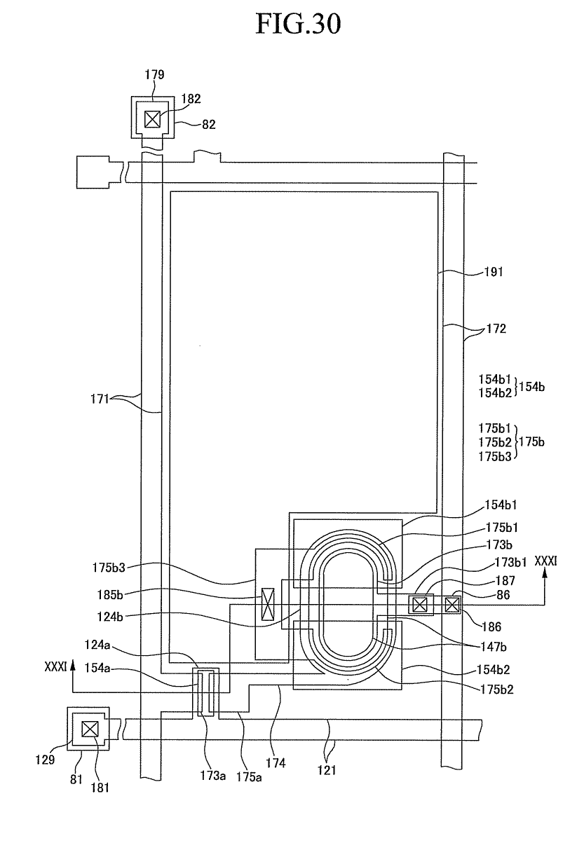

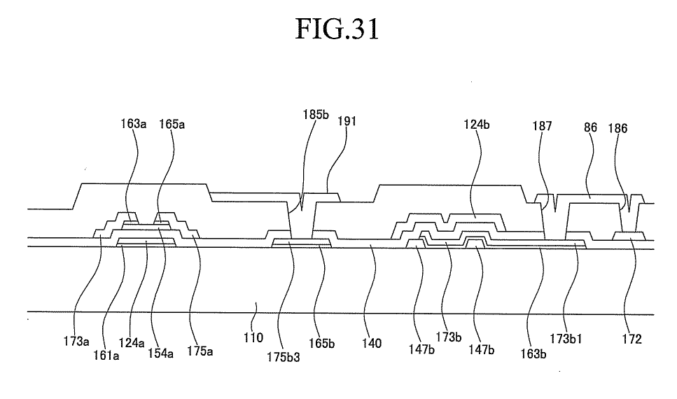

Next, as shown in FIGS. 30 and 31, a transparent conductive film is deposited on the passivation layer 180 by sputtering, etc., and is photo-etched to form a plurality of pixel electrodes 191, a plurality of connecting members 86, and a plurality of contact assistants 81 and 82.

The manufacturing processes that follow may be the same as that of the previous embodiment.

This embodiment may also obtain the same effects and advantages as that of the previous embodiment.

### EMBODIMENT 3

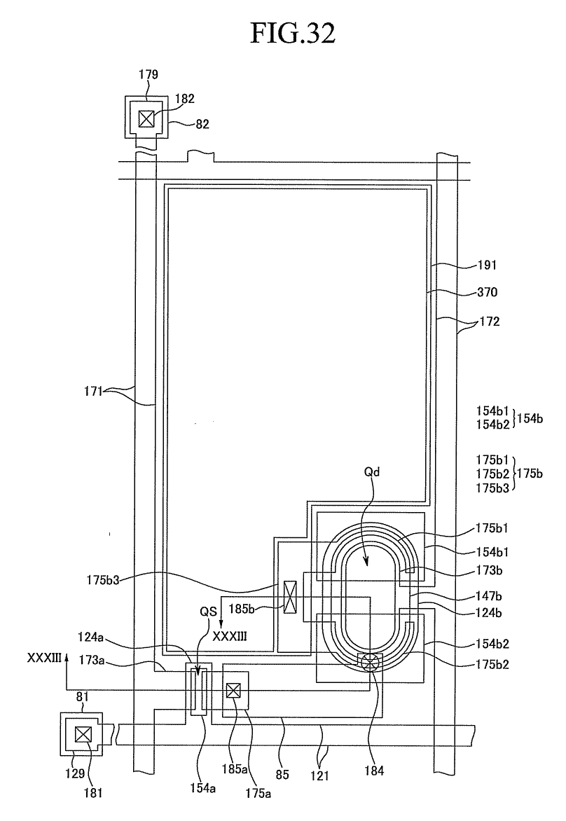

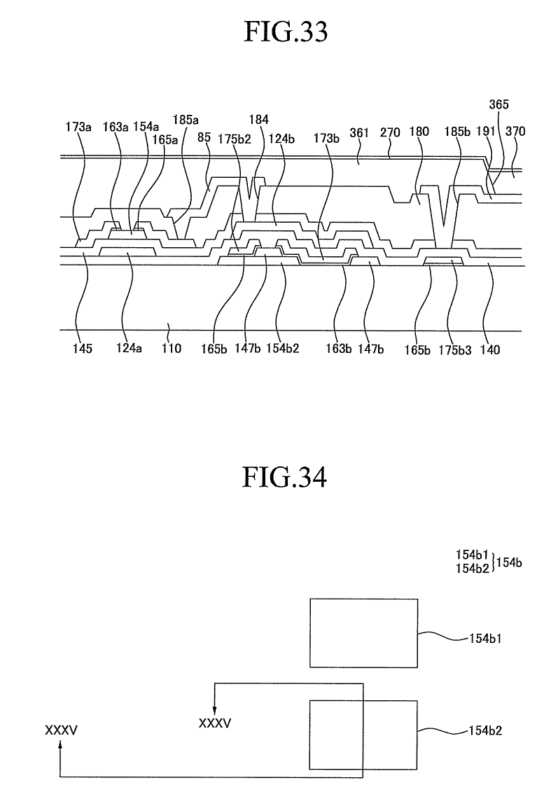

Referring to FIGS. 32 and 33, a detailed structure of an exemplary organic light emitting device shown in FIG. 1 according to another exemplary embodiment of the present invention will be described in detail.

FIG. 32 is an exemplary layout view of an exemplary organic light emitting device according to another exemplary embodiment of the present invention, and FIG. 33 is a sectional view of the exemplary organic light emitting device shown in FIG. 32, taken along line XXXIII-XXXIII. Detailed descriptions of elements having the same or substantially the same function as in the previous embodiments are omitted in this description of this embodiment according to the present invention, for convenience of description.

A plurality of driving semiconductor islands 154b including first and second portions 154b1 and 154b2 are formed on an insulating substrate 110, and a plurality of etch stoppers 147b having a running oval shape are formed thereon.

A plurality of driving voltage lines 172 including driving input electrodes 173b overlapping the inner boundary of the etch stoppers 147b and connection portions 173b1, and a plurality of driving output electrodes 175b including first and second portions 175b1 and 175b2 respectively overlapping the upper and the lower portions of the etch stoppers 147b, are formed on the substrate 110, the driving semiconductor islands 154b, and the etch stoppers 147b.

A plurality of pairs of ohmic contacts 163b and 165b are respectively formed between the semiconductor islands 154b, and the driving input and driving output electrodes 175b and 173b, respectively.

The ohmic contacts (not shown) may also be disposed under the driving voltage lines 172 with the same planar shapes as the driving voltage lines 172.

A plurality of gate lines 121 including switching control electrodes 124a and end portions 129, and a plurality of driving control electrodes 124b overlapping the etch stoppers 147b, are formed on a first gate insulating layer 140 covering the substrate 110, the driving semiconductor islands 154b, the etch stoppers 147b, the driving voltage lines 172, and the driving output electrodes 175b.

A second gate insulating layer 145 covering the gate lines 121 and the control electrodes 124b is formed on the first gate insulating layer 140, and a plurality of switching semiconductor islands 154a made of a-Si and overlapping the switching control electrodes 124a are formed thereon.

A plurality of data lines 171 including switching input electrodes 173a and end portions 179, and a plurality of switching output electrodes 175, are formed on the second gate insulating layer 145 and the switching semiconductor islands 154a.

A plurality of pairs of ohmic contacts 163a and 165a are respectively formed between the switching input and the switching output electrodes 173a and 175a, and the switching semiconductor islands 154a, respectively.

A passivation layer 180 is formed on the data lines 171 and the switching output electrodes 175a, and on exposed portions of the second gate insulating layer 145.

The passivation layer 180 has a plurality of contact holes 185a and 182 exposing the switching output electrodes 175a and the end portions 179 of the data lines 171, respectively. The passivation layer 180 and the second gate insulating layer 145 have a plurality of contact holes 181 and 184 exposing the driving control electrode 124b and the end portions 129 of the gate lines 121, respectively, and the passivation layer 180 and the first and second gate insulating layers 140 and 145 have a plurality of contact holes 185b exposing the connections 175b3 of the driving output electrodes 175b.

A plurality of pixel electrodes 191 connected to the driving output electrodes 175b, a plurality of connecting members 85 connecting the driving control electrodes 124b and the switching output electrodes 175a, and a plurality of contact assistants 81 and 82 respectively connected to the end portions 129 and 179 are formed on the passivation layer 180.

As described above, the switching semiconductor 154a of the organic light emitting device according to this embodiment is made of a-Si, while the driving semiconductor 155b of the organic light emitting device according to this embodiment is made of microcrystalline silicon or polycrystalline silicon. Accordingly, the switching TFT Qs and the driving TFT Qd of the organic light emitting device according to this embodiment have channels made of different materials such that the desired characteristics for switching TFTs Qs and driving TFTs Qd may be satisfied.

Now, an exemplary method of manufacturing the exemplary display panel shown in FIGS. 32 and 33 is described with reference to FIGS. 33 to 49 as well as FIGS. 32 and 33.

FIGS. 34, 36, 38, 40, 42, 44, 46, and 48 are layout views of the exemplary organic light emitting device shown in FIGS. 32 and 33 in intermediate steps of an exemplary manufacturing method thereof according to an exemplary embodiment of the present invention, and FIGS. 35, 37, 39, 41, 43, 45, 47, and 49 are sectional views of the exemplary organic light emitting device shown in FIGS. 34, 36, 38, 40, 42, 44, 46, and 48 taken along lines XXXV-XXXV, XXXVII-XXXVII, XXXIX-XXXIX, XLI-XLI, XLIII-XLIII, XLV-XLV, XLVII-XLVII, and XLIX-XLIX, respectively.

As shown in FIGS. 34 and 35, crystalline silicon layer is deposited and patterned by photolithography to form a plurality of driving semiconductor islands 154b on an insulating substrate 110.

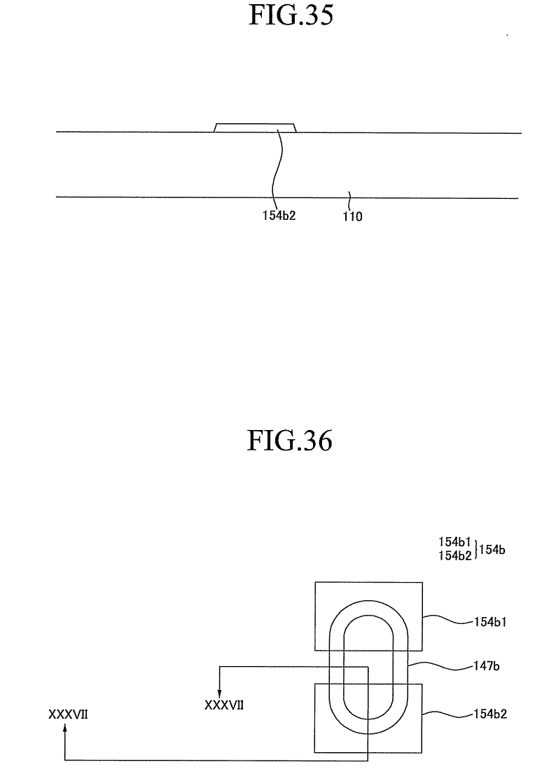

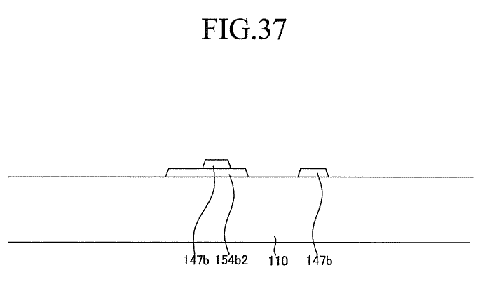

Next, as shown in FIGS. 36 and 37, an insulating layer is deposited on the substrate 110 and patterned to form a plurality of etch stoppers 147b with a running oval shape on the driving semiconductor islands 154b and the substrate 110.

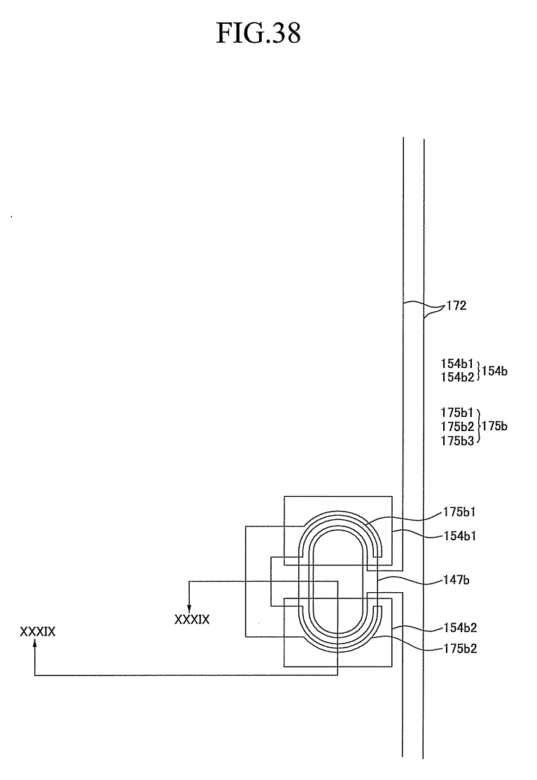

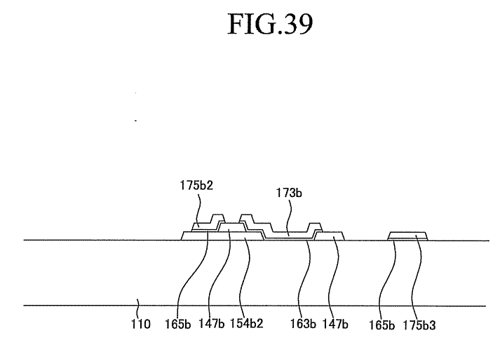

Then, as shown in FIGS. 38 and 39, an a-Si layer doped with impurities or a microcrystalline silicon layer, and a conductive layer, are sequentially deposited, and the conductive layer is patterned by photolithography to form a plurality of driving voltage lines 172 including driving input electrodes 173b and a plurality of driving output electrodes 175b. Next, the exposed silicon layer is removed to form a plurality of pairs of ohmic contacts 163b and 165b, and a plurality of ohmic contacts (not shown), underlying the driving voltage lines 172.

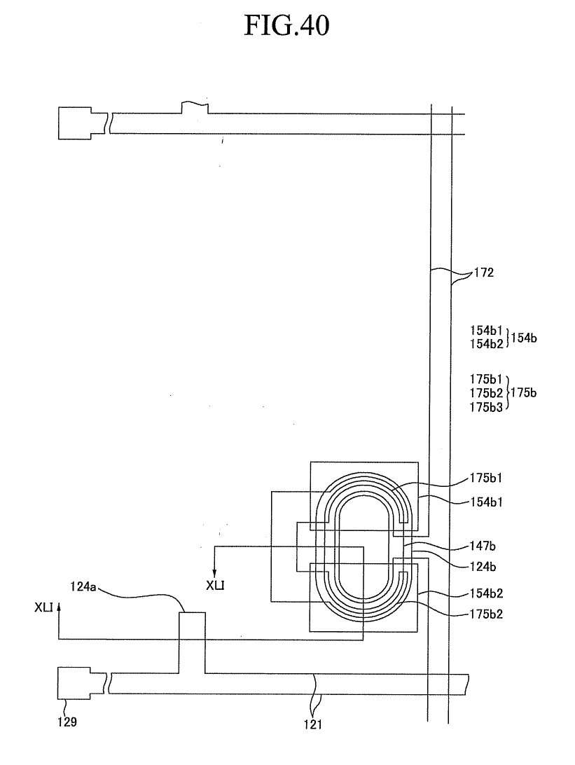

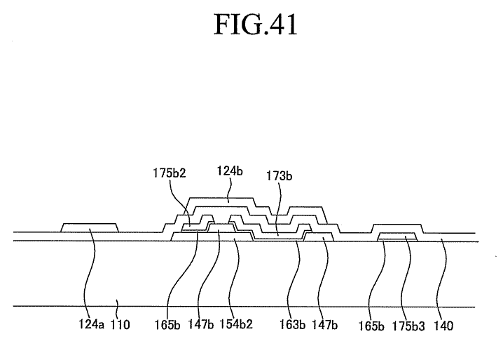

Next, as shown in FIGS. 40 and 41, a first gate insulating layer 140 is deposited, and then a conductive layer is deposited and patterned by photolithography to form a plurality of gate lines 121 including switching control electrodes 124a and end portions 129, and a plurality of driving control electrodes 124b.

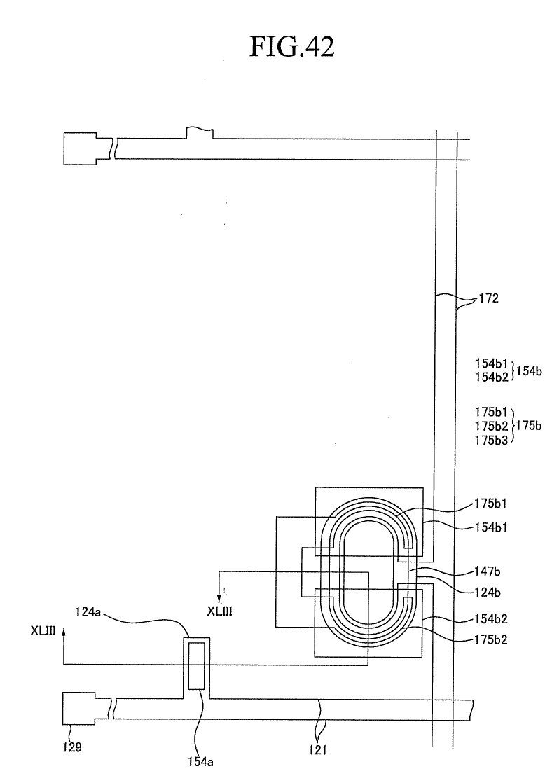

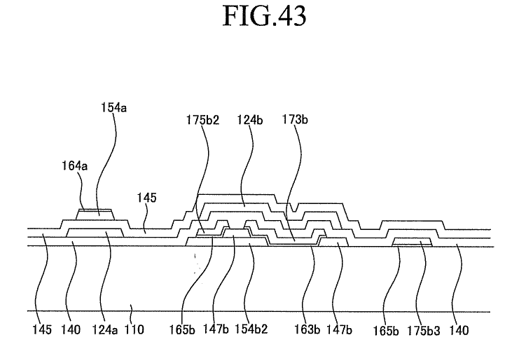

Next, as shown in FIGS. 42 and 43, a second gate insulating layer 145 made of silicon nitride, an intrinsic silicon layer, and an extrinsic silicon layer are sequentially formed on the gate lines 121 and the driving control electrodes 124b and on exposed portions of the first gate insulating layer 140, and the intrinsic silicon layer and the extrinsic silicon layer are photo-etched to form a plurality of switching semiconductor islands 154a and a plurality of ohmic contact layers 164a.

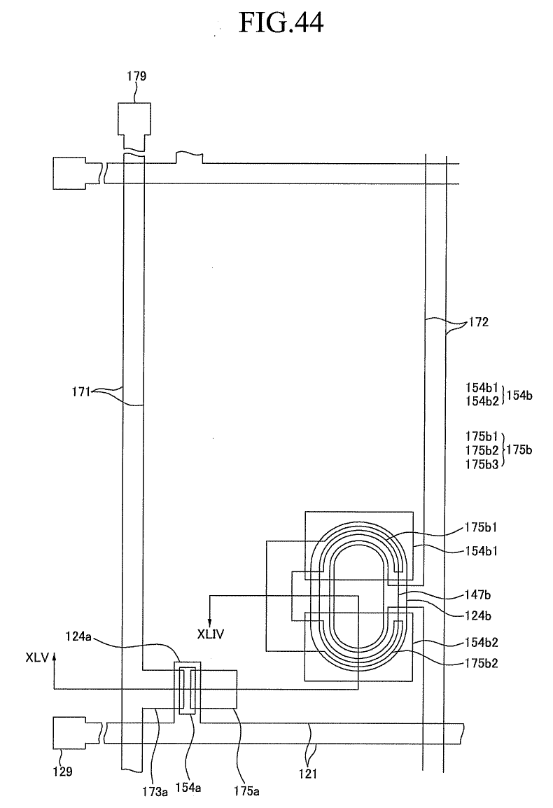

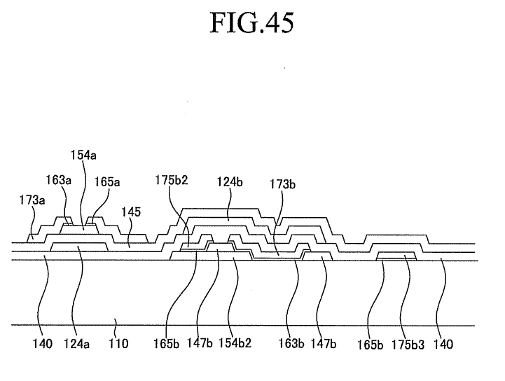

Next, as shown in FIGS. 44 to 45, a conductive layer is deposited on the switching semiconductor islands 154a, the ohmic contact layers 164a, and the second gate insulating layer 145, and the conductive layer is patterned by photolithography to form a plurality of data lines 171 including switching input electrodes 173a and end portions 179, and a plurality of switching output electrodes 175a. Next, the exposed portions of the ohmic contact layers 164a are removed to form a plurality of pairs of ohmic contacts 163a and 165a, respectively.

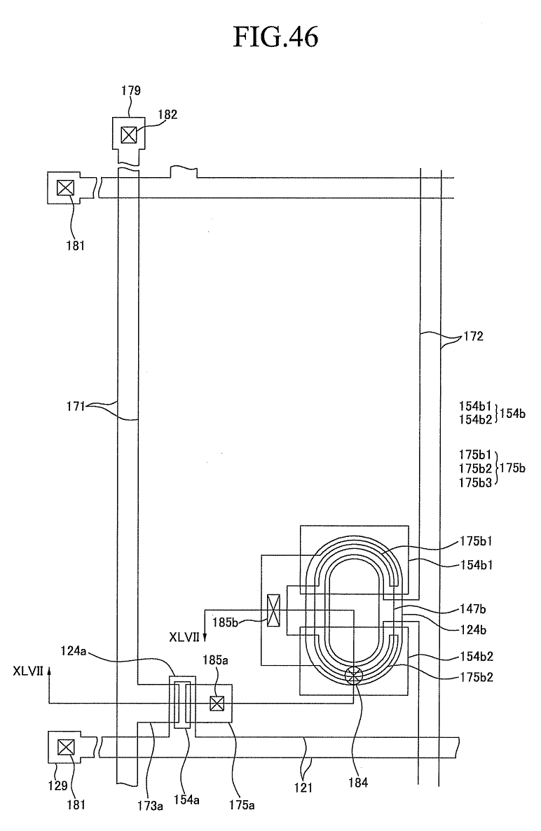

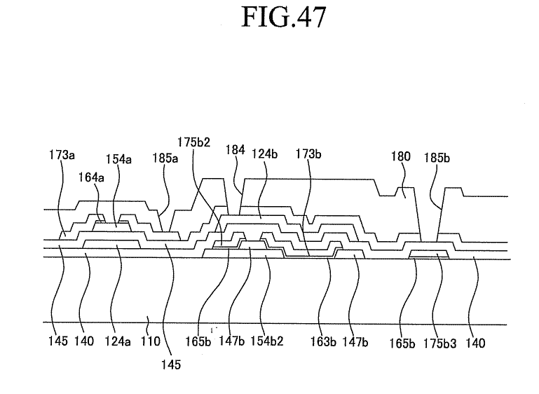

Referring to FIGS. 46 and 47, a passivation layer 180 is deposited by CVD, printing, etc., and patterned along with the first and second gate insulating layers 140 and 145 to form a plurality of contact holes 181, 182, 184, 185a, and 185b.

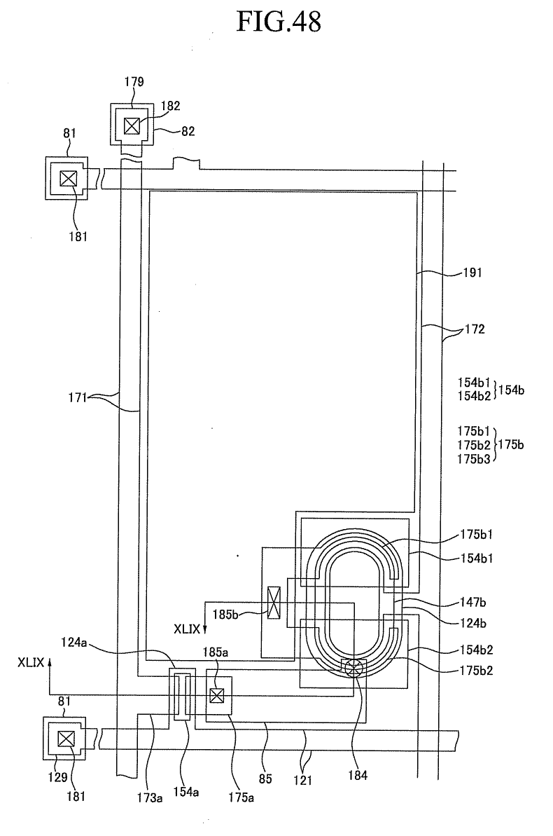

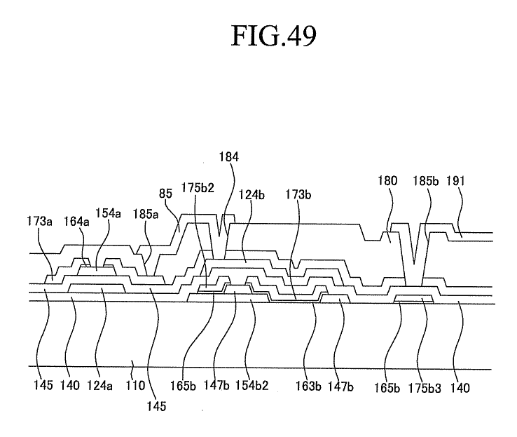

Next, as shown in FIGS. 48 and 49, a transparent conductive film is deposited on the passivation layer 180 by sputtering, etc., and is photo-etched to form a plurality of pixel electrodes 191, a plurality of connecting members 85, and a plurality of contact assistants 81 and 82.

The manufacturing process that follows may be the same or substantially the same as that of a prior embodiment, and therefore reference may be made to the above-described embodiment for a description of a subsequent manufacturing process.

This embodiment may also obtain the same effects and advantages as that of the previous embodiments.

As above-described, the various organic light emitting device embodiments are provided according to the kinds of the semiconductors, the positions of the gate lines, the driving voltage lines and the data lines, the crystalline silicon or a-Si of the driving and switching TFTs, and the metal layers of a double layered-structure and a triple layered-structure according to the connection relationships. However, in alternative exemplary embodiments, the driving TFTs may be arranged in a symmetrical structure with respect to the driving voltage lines, the driving voltage lines may be formed parallel to the gate lines, and the layered-structure and layout structure may be changed.

As will now be described below, under various exemplary embodiments, the structures of the driving TFTs will be described with reference to the drawings, and because the same structures as of the previous embodiments may be adapted to the following embodiments, the descriptions for the switching TFTs and the pixel structures will be omitted.

### EMBODIMENT 4

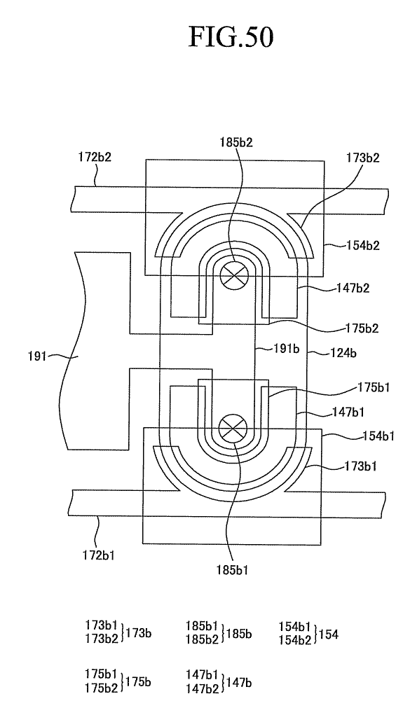

FIG. 50 is an exemplary layout view of an exemplary driving TFT in an exemplary organic light emitting device according to another exemplary embodiment of the present invention.

In an organic light emitting device according this exemplary embodiment of the present invention, a driving TFT is symmetrical with respect to the vertical central lines thereof, and the driving TFT has a driving semiconductor 154b, an etch stopper 147b, a driving input electrode 173b, and a driving output electrode 175b respectively including first and second portions 154b1, 154b2, 147b1, 147b2, 173b1, 173b2, 175b1, and 175b2. The first portion 173b1 of the driving input electrode 173b is connected to a left, or first, driving voltage line 172b1, and the second portion 173b2 of the driving input electrode 173b is connected to a right, or second, driving voltage line 172b2.

Because the first and second portions 147b1 and 147b2 of the etch stopper 147b have horseshoes shapes, the first and second portions 147b1 and 147b2 of the etch stopper 147b, and the first and second portions 154b1 and 154b2 of the driving semiconductor 154b overlap each other, and the overlapping sections also have horseshoe shapes. The inner overlapping portions of the etch stopper 147b and the driving semiconductor 154b respectively overlap with the first and second portions 175b1 and 175b2 of the driving output electrode 175b with horseshoe shapes, and the outer overlapping portions of the etch stopper 147b and the driving semiconductor 154b respectively overlap with the first and second portions 173b1 and 173b2 of the driving input electrode 173b parallel to the first and second portions 175b1 and 175b2 of the driving output electrode 175b. Evenly spaced gaps between the first and second portions 173b1 and 173b2 of the driving input electrode 173b and the first and second portions 175b1 and 175b2 of the driving output electrode 175b, respectively, also have horseshoe shapes. The etch stopper 147b and the driving input and driving output electrodes 173b and 175b are reversely and inversely symmetrical with respect to the vertical and horizontal lines, that is, first and second lines bisecting the etch stopper 147b, driving input electrodes 173b, and driving output electrodes 175b, where the first and second lines extend substantially parallel to and substantially perpendicular to the driving voltage lines 172b1 and 172b2, respectively.

A pixel electrode 191 includes a projection 191b extended toward the first and second portions 175b1 and 175b2 of the driving output electrode 175b, and the projection 191b is connected to the first and second portions 175b1 and 175b2 of the driving output electrode 175b though contact holes 185b1 and 185b2.

Also, a driving control electrode 124b has a running oval shape and overlaps the etch stopper 147b, the driving output electrode 175b, the driving input electrode 173b, and the driving semiconductor 154b.

In this exemplary organic light emitting device according to the present invention, the driving input electrodes 173b, the driving output electrodes 175b, and the etch stoppers 147b are respectively reverse symmetrical with respect to the vertical or horizontal central lines thereof. Therefore, even if the driving input electrodes 173b, the driving output electrodes 175b, and the etch stoppers 147b are misaligned in up/down and/or right/left directions, the characteristics of the driving TFTs remain uniform. For example, if the driving input electrodes 173b, the driving output electrodes 175b, and the etch stoppers 147b are misaligned, then one channel portion or off-set region of the driving TFT becomes narrower. However, the other channel portion or off-set region of the driving TFT becomes wider at the portion with the compensation. Accordingly, the characteristics of the driving TFT are not changed, thereby improving the characteristics of the display device as compared to a display device having a conventional driving TFT that is misaligned during manufacture.

In this exemplary organic light emitting device, each pixel may receive signals from two driving voltage lines. Here, driving input and output electrodes may be arranged with reverse symmetry with respect to each driving voltage line, and the driving voltage lines may be formed parallel to a gate line. It is preferable that the data lines, the gate lines, and the driving voltage lines are formed with different layers.

### EMBODIMENT 5

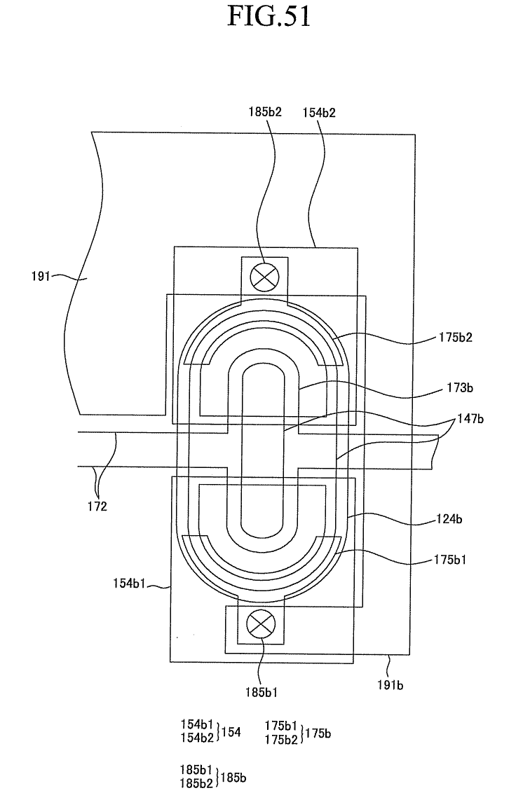

FIG. 51 is an exemplary layout view of an exemplary driving TFT in an exemplary organic light emitting device according to another exemplary embodiment of the present invention.

In an exemplary organic light emitting device according this exemplary embodiment of the present invention, a driving TFT is symmetrical with respect to a driving voltage line 172, and the TFT has a driving semiconductor 154b and a driving output electrode 175b respectively including first and second portions 154b1, 154b2, 175b1, and 175b2. Also, the driving TFT has an etch stopper 147b and a driving input electrode 173b connected to the driving voltage line 172. The etch stopper 147b and the driving input electrode 173b have running oval shapes. The oval shape of the etch stopper 147b may include an oval shaped opening symmetrically arranged with respect to the driving voltage line 172 and the oval shaped outer periphery of the etch stopper 147b. The driving input electrode 173b expands from the driving voltage line 172 in a direction towards the first portion 175b1 of the driving output electrode 175b and in a direction towards the second portion 175b2 of the driving output electrode 175b.

Because the etch stopper 147b has a running oval shape, the overlapping portions between the etch stopper 147b and the first and second portions 154b1 and 154b2 of the driving semiconductor 154b have horseshoe shapes. The first and second portions 154b1 and 154b2 of the driving semiconductor 154b are symmetrical with respect to the vertical central line thereof, such as a line bisecting the driving semiconductor 154b and extending substantially perpendicular to the driving voltage line 172. The first and second portions 154b1 and 154b2 of the driving semiconductor overlap with the upper and lower portions of a driving input electrode 173b with the horseshoe shape in the inner portions of the overlapping portions between the etch stopper 147b and the driving semiconductor 154b. The upper and lower portions 175b1 and 175b2 of a driving output electrode 175b overlap with the outer portions of the overlapping portions between the etch stopper 147b and the driving semiconductor 154b. Therefore, the etch stopper 147b, the driving input electrode 173b, and the driving output electrode 175b are reverse symmetrical with respect to the vertical and horizontal central lines, where the horizontal central line may be substantially defined by a longitudinal line of the driving voltage line 172. This structure has a shape in which the structures of the first to third exemplary embodiments are rotated by 90 degrees.

A pixel electrode 191 includes a projection 191b extended toward the first portion 175b1 of the driving output electrode 175b, while a main portion of the pixel electrode 191 may overlap with the second portion 175b2 of the driving output electrode 175b, and the projection 191b is connected to the first portion 175b1 of the driving output electrode 175b though contact hole 185b1 and the pixel electrode 191 is also connected to the second portion 175b2 of the driving output electrode 175b through contact hole 185b2.

In the exemplary organic light emitting device according to the present invention, the driving input electrodes 173b, the driving output electrodes 175b, and the etch stoppers 147b are respectively reverse symmetrical with respect to the vertical or horizontal central lines thereof. Therefore, even if misalignments are generated in up/down and/or right/left directions, the characteristics of the driving TFTs remain uniform, thereby improving the characteristics of the display device as compared to a display device having a conventional driving TFT that is misaligned during manufacture.

In this organic light emitting device, each pixel may receive signals from one driving voltage line. Here, the driving voltage line may extend parallel to the gate line or the data line and may be formed in the vertical or horizontal directions, and the data line, the gate line, and the driving voltage line may be formed with two or three layers.

### EMBODIMENT 6

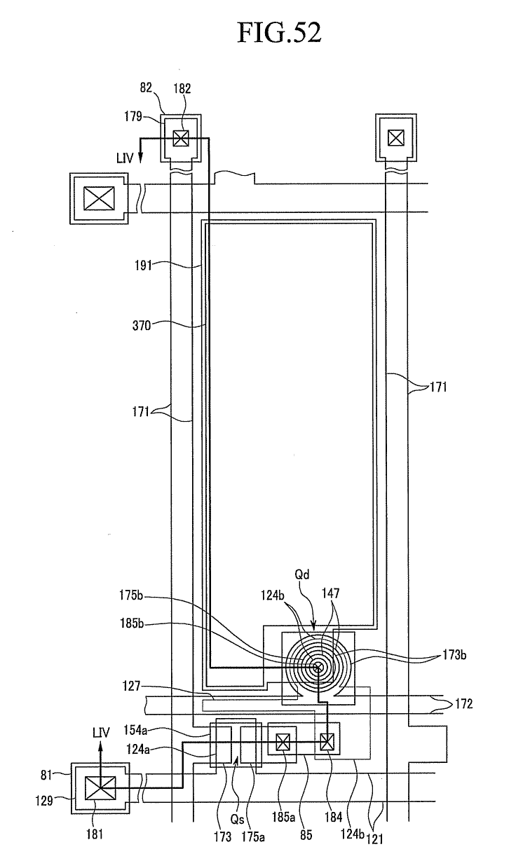

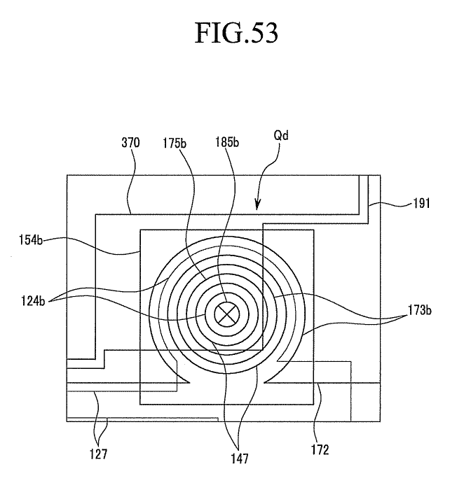

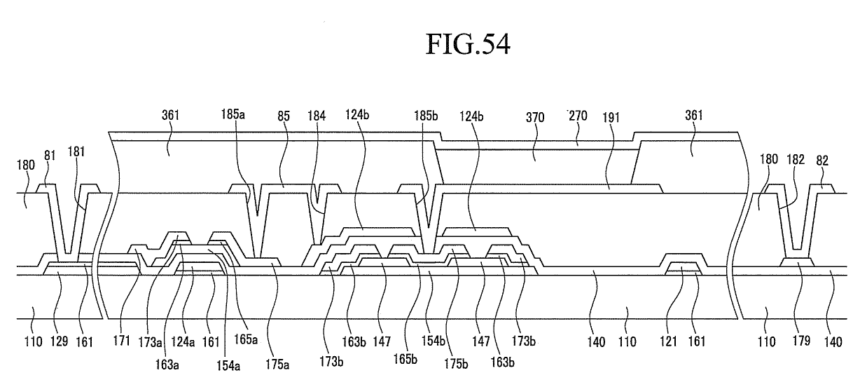

FIG. 52 is an exemplary layout view of an exemplary organic light emitting device according to another exemplary embodiment of the present invention, FIG. 53 is an enlarged layout view showing the exemplary driving TFT in the exemplary organic light emitting device shown in FIG. 52, and FIG. 54 is a sectional view of the exemplary organic light emitting device shown in FIG. 52, taken along line LIV-LUV.

A plurality of driving semiconductor islands 154b are formed on an insulating substrate 110, and a plurality of etch stoppers 147 with a donut shape including an opening located at the central portion and disposed on the central portion of the driving semiconductor islands 154b are formed.

A plurality of gate lines 121 including a switching control electrode 124a and an end portion 129, a plurality of driving input electrodes 173b and a plurality of driving output electrodes 175b, and a plurality of driving voltage lines 172 including the driving input electrodes 173b are formed on the substrate 110, the driving semiconductor islands 154b, and the etch stoppers 147.

The driving voltage lines 172 extend substantially in the longitudinal direction, the first direction, and substantially parallel to the gate lines 121 and include the driving input electrodes 173b. Here, the driving input electrodes 173b also each have a donut shape including an opening located at the central portion thereof, where the opening of each driving input electrode 173b is substantially concentric with the opening of the each corresponding etch stopper 147. The inner boundary of the driving input electrodes 173b is disposed on the etch stoppers 147 and the outer boundary of the driving input electrodes 173b is disposed on the substrate 110. Accordingly, the driving input electrodes 173b cover the circumferences of the outer overlapping portions of the driving semiconductor islands 154b and the etch stoppers 147.

The driving output electrodes 175b are separated from the gate lines 121 and the driving voltage lines 172 and are disposed within the inner boundary of the driving input electrodes 173b with circular shapes. The boundary of the driving output electrodes 175b is disposed on the etch stoppers 147 such that the driving output electrodes 175b cover the central portion of the driving semiconductor islands 154b and inner portions of the etch stoppers 147.

A plurality of pairs of ohmic contacts 163b and 165b are respectively formed between the semiconductor islands 154b and the driving voltage lines and driving output electrodes 172 and 175b, respectively. The ohmic contacts 163b and 165b have substantially the same planar shapes as the driving voltage lines 172 and the driving output electrodes 175b.

Also, a plurality of ohmic contacts 161 are formed under the gate lines 121 with substantially the same planar shapes as the gate lines 121.

A gate insulating layer 140 is formed on the gate lines 121, the driving voltage lines 172, the driving output electrodes 175b, and the driving semiconductor islands 154b, as well as on exposed portions of the substrate 110.

A plurality of switching semiconductor islands 154a preferably made of a-Si and overlapping the switching control electrodes 124a are formed on the gate insulating layer 140.

A plurality of data lines 171 including switching input electrodes 173a and an end portion 179, a plurality of switching output electrodes 175a, and a plurality of driving control electrodes 124b are formed on the switching semiconductor islands 154a and the gate insulating layer 140. The data lines 171 extend substantially perpendicular to the gate lines 121 and driving voltage lines 172.

The switching output electrodes 175a are separated from the data lines 171 and overlap the portions of the switching semiconductor islands 154a spaced from and opposite to the switching input electrodes 173a with the respect to the switching semiconductor islands 154a.

The driving control electrodes 124b with island shapes include storage electrodes 127 extended in the horizontal direction. The driving control electrodes 124b include donut shapes having an opening at the central portion, substantially concentric with the openings of the etch stopper 147 and driving input electrode 173b, and overlap the driving semiconductor islands 154b. The inner boundary of the donut-shaped portion of each driving control electrode 124b is disposed on the corresponding driving output electrode 175b and the outer boundary of the donut-shaped portion of each driving control electrode 124b is disposed on the corresponding driving input electrodes 173b. Accordingly, the driving control electrodes 124b overlap the driving semiconductor islands 154b between the driving input electrodes 173b and the driving output electrodes 175b, and overlap the portions of the driving input electrodes 173b and the driving output electrodes 175b.

A plurality of pairs of ohmic contacts 163a and 165a are respectively formed between the switching input and switching output electrodes 173a and 175a, and the switching semiconductor islands 154a, respectively.

A passivation layer 180 is formed on the data lines 171, the switching output electrodes 175a, and the driving control electrodes 124b, and on exposed portions of the gate insulating layer 140.

The passivation layer 180 and the gate insulating layer 140 have a plurality of contact holes 181 and 185b exposing the driving output electrodes 175b and the end portions 129 of the gate lines 121, respectively, and the passivation layer 180 has a plurality of contact holes 185a, 184, and 182 exposing the switching output electrodes 175a, the driving control electrodes 124b, and the end portions 179 of the data lines 171.

A plurality of pixel electrodes 191 connected to the driving output electrodes 175b, a plurality of connecting members 85 connecting the switching output electrodes 175a and the driving control electrodes 124b, and a plurality of contact assistants 81 and 82 respectively connected to the end portions 129 and 179 are formed on the passivation layer 180.

A partition 361, including openings 365, is formed on the pixel electrodes 191, the connecting members 85, and the contact assistants 81 and 82, as well as on exposed portions of the passivation layer 180.

A plurality of light emitting members 370 are formed on the pixel electrodes 191 and confined within the openings 365 defined by the partition 361.

The common electrode 270 is formed on the light emitting members 370 and the partition 361.

As described above, the switching semiconductor 154a of the organic light emitting device according to this embodiment is made of a-Si, while the driving semiconductor 154b of the organic light emitting device display according to this exemplary embodiment is made of microcrystalline silicon or polycrystalline silicon. The channel of the switching TFT Qs includes a-Si, while the channel of the driving TFT Qd includes microcrystalline silicon or polycrystalline silicon.

The driving TFT Qd may include a channel of microcrystalline silicon or polycrystalline silicon such that the driving TFT Qd may have carrier mobility and stability. Accordingly, the current flowing in the driving TFT Qd may increase to enhance luminance of the OLED according to the exemplary embodiment of the present invention. Also, the so-called threshold voltage shift phenomenon caused by applying a constant positive voltage in driving an OLED may be excluded such that an image sticking phenomenon is not generated and the life-time reduction of the OLED does not occur.

Meanwhile, the channel of the switching TFT Qs includes a-Si having a low off current. Accordingly the on/off characteristic of the switching TFT Qs for controlling the data voltage, particularly a reduction of the off current, may be maintained well such that the data voltage reduction due to a high off current may be prevented and the cross-talk phenomenon of the OLED may be reduced. If the channel of the switching TFT Qs included microcrystalline silicon or polycrystalline silicon, then the off current of the switching TFT Qs may be high to cause the data voltage to reduce and the cross-talk phenomenon of the OLED to occur.

As described above, the switching TFT Qs and the driving TFT Qd of the OLED display according to this exemplary embodiment have channels made of different materials such that the desired characteristics for the switching TFTs and driving TFTs may be satisfied.

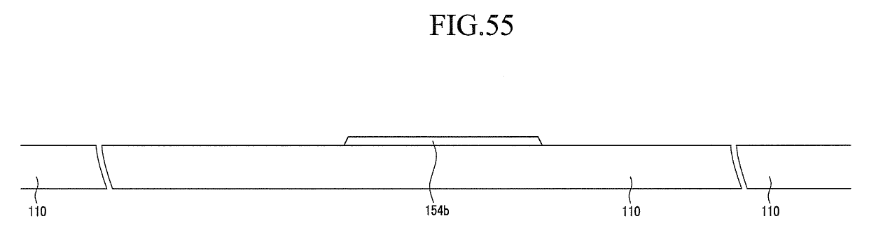

Now, an exemplary method of manufacturing the exemplary display panel shown in FIGS. 52 to 54 is described with reference to FIGS. 55 to 61 as well as FIGS. 52 to 54.

FIGS. 55 to 61 are sectional views of the exemplary organic light emitting device shown in FIGS. 52 to 54 in intermediate steps of an exemplary manufacturing method thereof according to an exemplary embodiment of the present invention.

As shown in FIG. 55, a-Si is deposited and then crystallized, or polycrystalline silicon is deposited on an insulating substrate 110 to form a polycrystalline silicon layer.

Next, the polycrystalline silicon layer is patterned by photolithography to form a plurality of driving semiconductor islands 154b.

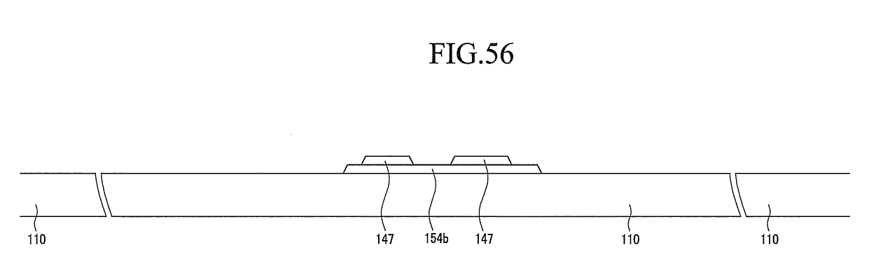

Next, as shown in FIG. 56, an insulating layer is deposited on the substrate 110, and patterned to form a plurality of etch stoppers 147 with donut shapes on the driving semiconductor islands 154b. Thereafter, H₂ plasma treatment is executed in order to stabilize the exposed surfaces of the driving semiconductor islands 154b.

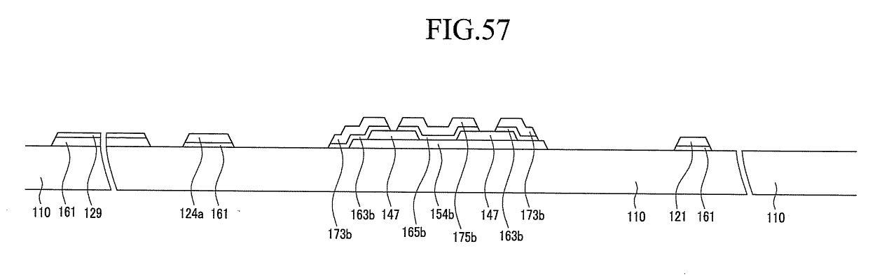

Then, as shown in FIG. 57, an a-Si layer doped with impurities or a microcrystalline silicon layer, and a conductive layer, are sequentially deposited, and the conductive layer is patterned by photolithography to form a plurality of gate lines 121 including switching control electrodes 124a and end portions 129, a plurality of driving voltage lines 172 including a plurality of driving input electrodes 173b, and a plurality of driving output electrodes 175b. Next, the exposed silicon layer is removed to form a plurality of pairs of ohmic contacts 161, 163b, and 165b, respectively.

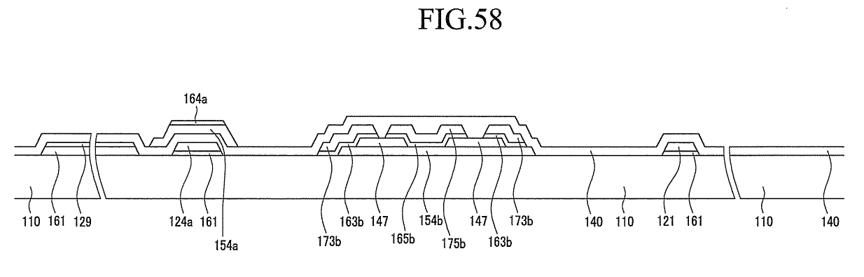

Next, as shown in FIG. 58, a gate insulating layer 140 made of silicon nitride, an intrinsic silicon layer, and an extrinsic silicon layer are sequentially formed on the gate lines 121, the driving voltage lines 172 and the driving output electrodes 175b, and on exposed portions of the substrate 110, and the intrinsic silicon layer and the extrinsic silicon layer are photo-etched to form a plurality of switching semiconductor islands 154a and a plurality of ohmic contact layers 164a.

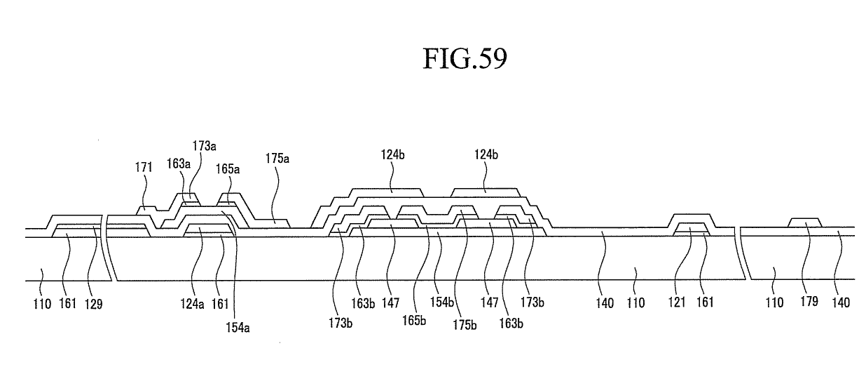

Next, as shown in FIG. 59, a conductive layer is deposited on the switching semiconductor islands 154a, the ohmic contact layers 164a, and the gate insulating layer 140, and the conductive layer is patterned by photolithography to form a plurality of data lines 171 including switching input electrodes 173a and end portions 179, a plurality of switching output electrodes 175a, and a plurality of driving control electrodes 124b. Next, the exposed portions of the ohmic contact layers 164a are removed to form a plurality of pairs of ohmic contacts 163a and 165a, respectively.

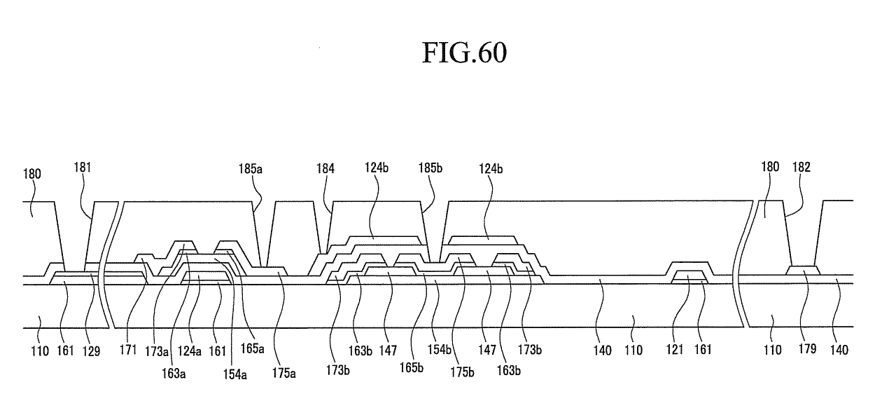

Referring to FIG. 60, a passivation layer 180 is deposited by CVD, printing, etc., and patterned along with the gate insulating layer 140 to form a plurality of contact holes 181, 182, 184, 185a, and 185b.

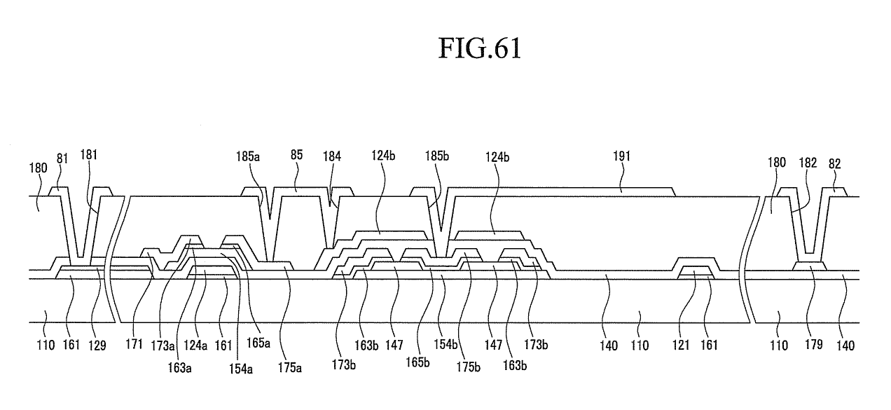

Next, as shown in FIG. 61, a transparent conductive film is deposited on the passivation layer 180 by sputtering, etc., and is photo-etched to form a plurality of pixel electrodes 191, a plurality of connecting members 85, and a plurality of contact assistants 81 and 82.

The manufacturing process that follows may be substantially the same as that of the previously described exemplary embodiments.

In this exemplary embodiment, the driving semiconductor islands 154b are firstly deposited and crystallized such that the driving semiconductor islands 154b may be crystallized, and the etch stoppers 147 are formed on the driving semiconductor islands 154b such that the driving semiconductor islands 154b may be prevented from being damaged when etching the ohmic contacts 163a and 165b and the driving semiconductor islands 154b may have a uniform thickness. Accordingly, the characteristics of the TFT may be uniformly improved.

Furthermore, the driving input electrodes 173b, the driving output electrodes 175b, and the etch stoppers 147 have a circular or donut shape in the driving TFTs, and the overlapping portions between the driving input electrodes 173b are disposed outside the overlapping portions between the driving output electrodes 175b and the etch stoppers 147. Here, the overlapping portions between the etch stoppers 147, and the driving input and driving output electrodes 173b and 175b have a donut shape or a circular belt shape with rotation symmetry with respect to the vertical or horizontal central line of the etch stoppers 147. Therefore, even if the driving output electrodes 175b, the driving input electrodes 173b, and the etch stoppers 147 become misaligned during the manufacturing process, the overlapping portions between the etch stoppers 147 and the driving input and driving output electrodes 173b and 175b are compensated to each other in the up/down and/or right/left directions, and are uniformly maintained. Accordingly, the characteristics of the TFTs may be uniformly obtained thereby improving the quality of the display device.

### EMBODIMENT 7

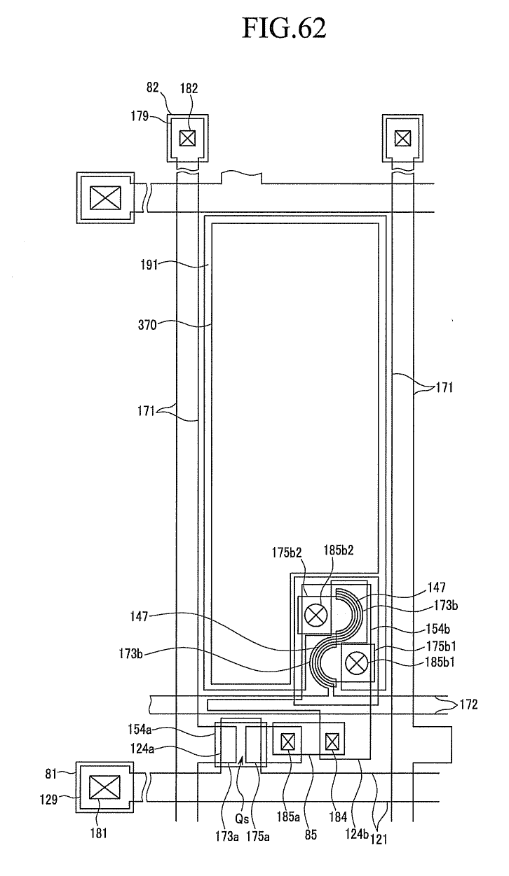

Referring to FIG. 62, a detailed structure of an exemplary organic light emitting device shown in FIG. 1 according to another exemplary embodiment of the present invention will be described in detail.

FIG. 62 is an exemplary layout view of an exemplary organic light emitting device according to another exemplary embodiment of the present invention.

The layered structure of this embodiment according to the present invention may be substantially the same as that of FIGS. 52 to 54.

A plurality of driving semiconductor islands 154b made of crystalline silicon are formed on an insulating substrate 110, and a plurality of etch stoppers 147 are formed thereon. Next, a plurality of gate lines 121 including a switching control electrode 124a and an end portion 129, a plurality of driving input electrodes 173b and a plurality of driving output electrodes 175b, and a plurality of driving voltage lines 172 including the driving input electrodes 173b are formed thereon, and a plurality of pairs of ohmic contacts 161, 163b, and 165b are respectively formed between the semiconductor islands 154b and the driving voltage lines 172 and driving output electrodes 175b and 172, respectively, and between the gate lines 121 and the substrate 110. Then, a plurality of switching semiconductor islands 154a preferably made of a-Si and overlapping the switching control electrodes 124a are formed on a gate insulating layer 140 covering the gate lines 121, the driving voltage lines 172, the driving output electrodes 175b, the driving semiconductor islands 154b, and exposed portions of the substrate 110. A plurality of data lines 171 including switching input electrodes 173a and an end portion 179, a plurality of switching output electrodes 175a, and a plurality of driving control electrodes 124b are formed on the switching semiconductor islands 154a and the gate insulating layer 140, and a plurality of pairs of ohmic contacts 163a and 165a are respectively formed between the switching input and switching output electrodes 173a and 175a, and the switching semiconductor islands 154a, respectively. The driving control electrode 124b may include a storage electrode portion overlapping with the driving voltage line 172. A passivation layer 180 is formed on the data lines 171, the switching output electrodes 175a, the driving control electrodes 124b, and exposed portions of the gate insulating layer 140, the passivation layer 180 and the gate insulating layer 140 have a plurality of contact holes 181 and 185b exposing the driving output electrodes 175b and the end portions 129 of the gate lines 121, respectively, and the passivation layer 180 has a plurality of contact holes 185a, 184, and 182 exposing the switching output electrodes 175a, the driving control electrodes 124b, and the end portions 179 of the data lines 171. Next, a plurality of pixel electrodes 191 connected to the driving output electrodes 175b, a plurality of connecting members 85 connecting the switching output electrodes 175a and the driving control electrodes 124b, and a plurality of contact assistants 81 and 82 respectively connected to the end portions 129 and 179 are formed on the passivation layer 180. A partition 361 including openings 365 is formed on the pixel electrodes 191, the connecting members 85, the contact assistants 81 and 82, and the passivation layer 180, and a plurality of light emitting members 370 and a common electrode 270 are sequentially formed on the pixel electrodes 191, and the light emitting members 370 are confined in the openings 365 defined by the partition 361.

In this exemplary embodiment, the etch stoppers 147 and the driving input electrodes 173b have an “S” shape which includes two connected half-moon portions. The driving input electrodes 173b overlap the outer portions of the etch stoppers 147, and the driving output electrodes 175b are divided into two portions 175b1 and 175b2 each having a corresponding curved end and respectively overlapping with the inner portions of the etch stoppers 140. The driving control electrodes 124b overlap the portions to which the driving input and driving output electrodes 173b and 175b are disposed adjacent to, and the portions of the etch stoppers 147 therebetween.

In this exemplary embodiment, the etch stoppers 147 and the driving input and driving output electrodes 173b and 175b have rotation symmetry with respect to the vertical or horizontal central line thereof. Therefore, even if misalignments are generated such as in the previous exemplary embodiments in the manufacturing process, the characteristics of the TFTs may be uniformly maintained thereby improving the quality of the display device.

As above-described, the etch stoppers and the driving input and driving output electrodes that the driving semiconductors overlap have rotation symmetry or reverse symmetry with respect to the vertical or horizontal central lines thereof. Therefore, even if misalignments are generated during the manufacturing process, the characteristics of the TFTs may be uniformly maintained thereby improving the quality of the display device.

Although exemplary embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. An organic light emitting device comprising:
a substrate;
first and second signal lines formed on the substrate;
a switching thin film transistor connected to the first and second signal lines and including a first semiconductor;
a driving thin film transistor including a second semiconductor, an etch stopper formed on the second semiconductor, driving input and driving output electrodes overlapping the etch stopper and the second semiconductor and opposite to each other with respect to the etch stopper, and a driving control electrode connected to the switching thin film transistor and overlapping the second semiconductor;
a first electrode connected to the driving output electrode;
a second electrode opposite to the first electrode; and
an organic light emitting member,
wherein at least one of the etch stopper, the driving input electrode, and the driving output electrode is symmetrical with respect to one straight line.

2. The organic light emitting device of claim 1, wherein the second semiconductor has a first portion and a second portion separated from the first portion.

3. The organic light emitting device of claim 2, wherein the etch stopper includes a running oval shape, and wherein the driving input electrode overlaps an inner portion of the etch stopper and the driving output electrode overlaps an outer portion of the etch stopper.

4. The organic light emitting device of claim 3, wherein the driving output electrode includes first and second portions disposed on opposing sides of the etch stopper, and a third portion connecting the first and second portions of the etch stopper to each other.

5. The organic light emitting device of claim 1, further comprising a third signal line connected to the driving input electrode of the driving thin film transistor.

6. The organic light emitting device of claim 5, wherein the etch stopper, the driving input electrode, and the driving output electrode are symmetrical with respect to the third signal line.

7. The organic light emitting device of claim 6, wherein the driving output electrode and the second semiconductor each respectively have two portions and the two portions of each of the driving output electrode and the second semiconductor are separated from each other at opposite sides with respect to the third signal line.

8. The organic light emitting device of claim 1, wherein the driving input electrode comprises a first portion and a second portion separated from the first portion of the driving input electrode, and further comprises:
a first driving voltage line connected to the first portion of the driving input electrode; and
a second driving voltage line connected to the second portion of the driving input electrode.

9. The organic light emitting device of claim 8, wherein the etch stopper and the driving output electrode each include first and second portions separated from each other and formed with reverse symmetry.

10. The organic light emitting device of claim 9, wherein the first and second portions of the etch stopper include horseshoe shapes, the first and second portions of the driving output electrode respectively overlap inner portions of the first and second portions of the etch stopper, and the first and second portions of the driving input electrode respectively overlap outer portions of the first and second portions of the etch stopper.

11. The organic light emitting device of claim 10, further comprising a plurality of first electrodes, wherein the first and second portions of the driving output electrode are respectively connected to a same first electrode.

12. The organic light emitting device of claim 1, wherein the first and second semiconductors have different crystalline structures.

13. The organic light emitting device of claim 12, wherein the first semiconductor includes amorphous silicon and the second semiconductor includes polycrystalline silicon or microcrystalline silicon.

14. The organic light emitting device of claim 1, wherein the first and the second semiconductors are made of polycrystalline silicon or microcrystalline silicon.

15. The organic light emitting device of claim 1, wherein the switching thin film transistor further comprises:
a switching control electrode connected to the first signal line under the first semiconductor and insulated from the first semiconductor;
a switching input electrode connected to the second signal line and overlapping the first semiconductor; and
a switching output electrode connected to the driving control electrode and facing the switching input electrode on the first semiconductor.

16. The organic light emitting device of claim 15, wherein the switching control electrode is made with a same layer as the driving input electrode and the driving output electrode, and the switching input electrode and the switching output electrode are made with a same layer as the driving control electrode.

17. The organic light emitting device of claim 16, wherein the switching control electrode and the driving control electrode are formed on an insulating layer covering the driving input electrode and the driving output electrode.

18. The organic light emitting device of claim 15, wherein the driving input electrode, the driving output electrode, the switching input electrode, and the switching output electrode are made with a same layer.

19. The organic light emitting device of claim 18, wherein the switching control electrode and the driving control electrode are made with a same layer.

20. The organic light emitting device of claim 19, further comprising a connecting member connecting the driving control electrode to the switching output electrode and made of a same layer as the first electrode.

21. The organic light emitting device of claim 15, wherein the switching control electrode and the driving control electrode, the driving input electrode and the driving output electrode, and the switching input electrode and the switching output electrode are made with different layers.

22. The organic light emitting device of claim 1, wherein overlapping portions between the etch stopper and the driving input and driving output electrodes are compensated to each other when misaligned from each other to substantially uniformly maintain characteristics of the driving thin film transistor.

23. A method for manufacturing an organic light emitting device, the method comprising:
forming a switching semiconductor and a driving semiconductor on a substrate;
respectively forming etch stoppers on the switching and driving semiconductors;
forming a driving voltage line including a driving input electrode, a driving output electrode, a data line including a switching input electrode, and a switching output electrode;
forming a gate insulating layer covering the driving voltage line, the driving output electrode, the data line, and the switching output electrode;
forming a gate line including a switching control electrode, and a driving control electrode; and
forming a pixel electrode connected to the driving output electrode, and a connecting member connecting the switching output electrode to the driving control electrode.

24. The method of claim 23, wherein forming the driving semiconductor includes forming first and second spaced portions of the driving semiconductor on the substrate, and forming a driving output electrode includes forming first and second portions surrounding and spaced from opposite ends of the driving input electrode and a connection connecting the first and second portions of the driving output electrode to each other.

25. A method for manufacturing an organic light emitting device, the method comprising:
forming a driving semiconductor on a substrate;
forming an etch stopper on the driving semiconductor;
forming a driving input electrode, a driving output electrode, and a gate line including a switching control electrode;
forming a gate insulating layer covering the gate line, the driving output electrode, and the driving output electrode;
forming a switching semiconductor on the gate insulating layer;
forming a driving voltage line, a data line including a switching input electrode, and a driving control electrode; and
forming a pixel electrode connected to the driving output electrode, and a connecting member connecting the driving voltage line to the driving input electrode.

26. A method for manufacturing an organic light emitting device, the method comprising:
forming a driving semiconductor on a substrate;
forming an etch stopper on the driving semiconductor;
forming a driving voltage line including a driving input electrode, and a driving output electrode;
forming an interlayer insulating layer covering the driving voltage line and the driving output electrode;
forming a gate line including a switching control electrode, and a driving control electrode on the interlayer insulating layer;
forming a gate insulating layer covering the gate line and the driving control electrode;
forming a switching semiconductor on the gate insulating layer;
forming a data line including a switching input electrode, and a switching output electrode; and
forming a pixel electrode connected to the driving output electrode, and a connecting member connecting the switching output electrode to the driving control electrode.

27. An organic light emitting device comprising:
a substrate;
first and second signal lines formed on the substrate;
a switching thin film transistor connected to the first and second signal lines and including a first semiconductor;
a driving thin film transistor including a second semiconductor, an etch stopper formed on the second semiconductor, driving input and driving output electrodes overlapping the etch stopper and the second semiconductor and opposite to each other with respect to the etch stopper, and a driving control electrode connected to the switching thin film transistor and overlapping the second semiconductor;
a first electrode connected to the driving output electrode;
a second electrode opposite to the first electrode; and
an organic light emitting member,
wherein at least one of the etch stopper, the driving input electrode, and the driving output electrode has rotation symmetry with respect to a vertical or horizontal central line.

28. The organic light emitting device of claim 27, wherein overlapping portions between the etch stopper, and the driving input electrode and driving output electrode include a donut shape.

29. The organic light emitting device of claim 28, wherein an overlapping portion between the etch stopper and the driving output electrode is disposed in an overlapping portion between the etch stopper and the driving input electrode.

30. The organic light emitting device of claim 27, wherein overlapping portions between the etch stopper and the driving input electrode and driving output electrode include an “S” shape.

31. The organic light emitting device of claim 30, wherein the driving input electrode is a curved driving input electrode, and the driving output electrode includes two portions enclosed by the curved driving input electrode.

32. The organic light emitting device of claim 27, wherein the first and second semiconductors have different crystalline structures.

33. The organic light emitting device of claim 32, wherein the first semiconductor is made of amorphous silicon and the second semiconductor is made of polycrystalline silicon or microcrystalline silicon.

34. The organic light emitting device of claim 27, wherein the switching thin film transistor further comprises:
a switching control electrode connected to the first signal line under the first semiconductor and insulated from the first semiconductor;
a switching input electrode connected to the second signal line and overlapping the first semiconductor; and
a switching output electrode connected to the driving control electrode and facing the switching input electrode on the first semiconductor.

35. The organic light emitting device of claim 34, further comprising a gate insulating layer covering the driving input electrode, the driving output electrode, and the etch stopper.

36. The organic light emitting device of claim 35, wherein the driving input electrode, the driving output electrode, and the switching control electrode are made with a same layer.

37. The organic light emitting device of claim 36, wherein the switching input electrode, the switching output electrode, and the driving control electrode are made with a same layer.
